(19) United States
(12) Patent Application Publication
(10) Pub. No.: US 2026/0066861 A1
(43) Pub. Date: Mar. 5, 2026

(54) METHODS AND APPARATUS TO REGULATE AN OFFSET OF A COMMON MODE VOLTAGE FOR AMPLIFIER CIRCUITRY

(71) Applicant: Texas Instruments Incorporated, Dallas, TX (US)

(72) Inventors: Zhenzhen Chen, Shanghai (CN); Jianquan Liao, Shanghai (CN); Chi Cheong, Frisco, TX (US)

(21) Appl. No.: 18/821,461

(22) Filed: Aug. 30, 2024

(51) Int. Cl. H03F 3/45

(52) U.S. Cl. CPC H03F 3/45475; H03F 3/45183; H03F 2200/03; H03F 2200/375

(57) ABSTRACT

An example apparatus includes: amplifier circuitry having a first input, a second input, and an output; a resistor having a first terminal and a second terminal, the first terminal of the resistor coupled to the output of the amplifier circuitry; a first switch having a first terminal and a second terminal; a second switch having a first terminal and a second terminal; a third switch having a first terminal and a second terminal, the first terminal of the third switch coupled to the first terminal of the second switch; a fourth switch having a first terminal and a second terminal, the first terminal of the fourth switch coupled to the first terminal of the first switch; a first transistor having a first terminal and a second terminal; and a second transistor having a first terminal and a second terminal.

### TECHNICAL FIELD

This description relates generally to regulating common mode voltages and, more particularly, to methods and apparatus to regulate an offset of a common mode voltage for amplifier circuitry.

### BACKGROUND

Electronic systems utilize amplifier circuitry for a wide range of operations, such as for signal modulation. Such amplifier circuitry generates a modulated output signal by modulating a carrier signal based on an information signal. A load performs operations responsive to characteristics of the modulated output signal. In audio systems, amplifier circuitry modulates a carrier signal based on an information signal to generate a modulated output signal that is a relatively higher power signal and relatively high noise immunity than the information signal. Some amplifier circuitry includes feedback paths to modulate a relatively less complex signal in relation to a modulated signal at an output. Using amplifier circuitry for signal modulation allows electronic systems to generate increasingly complex signals from relatively less complex signals.

### SUMMARY

For methods and apparatus to regulate an offset of a common mode voltage for amplifier circuitry, an example apparatus includes amplifier circuitry having a first input, a second input, and an output; a resistor having a first terminal and a second terminal, the first terminal of the resistor coupled to the output of the amplifier circuitry; a first switch having a first terminal and a second terminal; a second switch having a first terminal and a second terminal; a third switch having a first terminal and a second terminal, the first terminal of the third switch coupled to the first terminal of the second switch; a fourth switch having a first terminal and a second terminal, the first terminal of the fourth switch coupled to the first terminal of the first switch; a first transistor having a first terminal and a second terminal, the first terminal of the first transistor coupled to the first input of the amplifier circuitry and the second terminal of the resistor, the second terminal of the first transistor coupled to the second terminal of the first switch and the second terminal of the fourth switch; and a second transistor having a first terminal and a second terminal, the first terminal of the second transistor coupled to the second input of the amplifier circuitry, the second terminal of the second transistor coupled to the second terminal of the second switch and the second terminal of the third switch. Other examples are described.

For methods and apparatus to regulate an offset of a common mode voltage for amplifier circuitry, an example apparatus includes amplifier circuitry having a first input and a second input; a first switch having a terminal and a second terminal; a second switch having a first terminal and a second terminal, the first terminal of the second switch coupled to the first terminal the first switch; a third switch having a first terminal and a second terminal; a fourth switch having a first terminal and a second terminal, the first terminal of the fourth switch coupled to the first terminal of the third switch; a first transistor having a first terminal, a second terminal, and a control terminal, the first terminal of the first transistor coupled to the second terminal of the first switch and the first terminal of the third switch; a second transistor having a first terminal, a second terminal, and a control terminal, the first terminal of the second transistor coupled to second terminal of the second switch and the second terminal of the fourth switch; and control circuitry having a first terminal, a second terminal, and a third terminal, the first terminal of the control circuitry coupled to the first input of the amplifier circuitry and the second terminal of the first transistor, the second terminal of the control circuitry coupled to the second input of the amplifier circuitry and the second terminal of the second transistor, the third terminal of the control circuitry coupled to the control terminal of the first transistor and the control terminal of the second transistor. Other examples are described.

For methods and apparatus to regulate an offset of a common mode voltage for amplifier circuitry, an example apparatus includes amplifier circuitry having a first input, a second input, and an output; common mode regulator circuitry having a terminal coupled to the output of the amplifier circuitry, the common mode regulator circuitry configured to: generate a first current and a second current responsive to a difference between a first input voltage at the first input of the amplifier circuitry and an output voltage at the output of the amplifier circuitry; regulate a common mode voltage of the first input voltage and a second input voltage at the second input of the amplifier circuitry responsive to generating the first current and the second current; compensate the first input voltage and the second input voltage for mismatch between the first current and the second current; and compensate the first current and the second current for a difference between the first input voltage and the second input voltage. Other examples are described.

### BRIEF DESCRIPTION OF THE DRAWINGS

FIG. 1 is a block diagram of an example amplifier system including example amplifier circuitry and example common mode regulator circuitry.

FIG. 2 is a block diagram of an example audio system including example multi-class modulation circuitry and example common mode regulator circuitry.

FIG. 3 is a schematic diagram of an example of the common mode regulator circuitry of FIGS. 1 and 2 including example mismatch correction circuitry.

FIG. 4 is a schematic diagram of an example of the mismatch correction circuitry of FIG. 3.

FIG. 5 is a schematic diagram of an example of the mismatch correction circuitry of FIGS. 3 and 4 including example control circuitry.

FIG. 6 is a flowchart representative of example machine-readable instructions or example operations that may be at least one of executed, instantiated, or performed using an example implementation of the mismatch correction circuitry of FIGS. 3, 4, and 5 or more generally the common mode regulator circuitry of FIGS. 1, 2, and 3.

FIG. 7 is a schematic diagram of another example of the mismatch correction circuitry of FIGS. 3, 4, and 5 and another example of the control circuitry of FIG. 5.

FIG. 8 is a block diagram of another example of the common mode regulator circuitry of FIGS. 1, 2, and 3 including first example mismatch correction circuitry and second example mismatch correction circuitry.

FIG. 9 is a schematic diagram of an example of the first mismatch correction circuitry of FIG. 8 and an example of the second mismatch correction circuitry of FIG. 8.

FIG. 10 is a flowchart representative of example machine-readable instructions or example operations that may be at least one of executed, instantiated, or performed using an example implementation of the mismatch correction circuitry of FIGS. 7, 8, and 9 or more generally the common mode regulator circuitry of FIGS. 1, 2, 3, and 8.

The drawings are not necessarily to scale. Generally, the same reference numbers in the drawing(s) and this description refer to the same or similar (functionally and/or structurally) features and/or parts. Although the drawings show regions with clean lines and boundaries, some or all of these lines and boundaries may be idealized. In reality, the boundaries or lines may be unobservable, blended or irregular.

### DETAILED DESCRIPTION

Electronic systems utilize amplifier circuitry for a wide range of operations, such as for signal modulation. Such amplifier circuitry generates a modulated output signal by modulating a carrier signal based on an information signal. A load performs operations responsive to characteristics of the modulated output signal. In audio systems, amplifier circuitry modulates a carrier signal based on an information signal to generate a modulated output signal that is a relatively higher power signal and relatively high noise immunity than the information signal. Some amplifier circuitry includes feedback paths to modulate a relatively less complex signal in relation to a modulated signal at an output. Using amplifier circuitry for signal modulation allows electronic systems to generate increasingly complex signals from relatively less complex signals.

As electronics continue to advance, signal modulation techniques continue to become increasingly complex. A method of single inductor (1L) modulation utilizes class AB and class D amplifier circuitry to modulate an input signal using a carrier signal. The class AB and class D amplifier circuitry receive a sinusoidal signal as an input signal to be modulated in relation to a triangular carrier signal. The class AB amplifier circuitry modulates the sinusoidal signal to generate a linear output signal. The linear output signal linearly transitions between logic levels, such as a linear transition between a logic high state and a logic low state. The class D amplifier circuitry modulates the sinusoidal input signal by comparing the sinusoidal signal to the triangular carrier signal. The class D amplifier circuitry generates a digital output signal having a varying duty cycle that represents the sinusoidal input signal. The duty cycle of the digital output signal represents amplitudes of the sinusoidal input signal. The class AB and class D amplifier circuitry also step up the input signal from an input power domain to an output power domain.

In some systems, the amplifier circuitry generates the output signal using a twenty-volt output supply voltage while the input signal uses a five-volt input supply voltage. In such systems, structuring the amplifier circuitry for closed loop operations increases the accuracy of the output signal. However, the differences between the power domain of the input signal and the power domain of the output signal result in relatively large feedback currents flowing through the current path between the input and output of the amplifier circuitry. Such currents may modify the common mode voltage of the input signal. In audio systems, when modulating an audio input signal, the amplifier circuitry amplifies changes in the common mode voltage of the audio input signal, which results in undesirable audio disturbances (e.g., audio clipping).

Some systems prevent such common mode voltage errors by including common mode regulator circuitry to regulate the common mode voltage at the input of the amplifier circuitry. In such systems, the common mode regulator circuitry includes current regulator circuitry and error amplifier circuitry. The current regulator circuitry monitors voltages at the output of the amplifier circuitry to determine a feedback current. The current regulator circuitry represents the current flowing through a current path between an input and output of the amplifier circuitry. The current regulator circuitry sinks (e.g., sources current from) the feedback current from input(s) of the amplifier circuitry and output(s) of the error amplifier circuitry. The error amplifier circuitry compares a common mode voltage at the input(s) of the amplifier circuitry to a reference voltage, which represents a target common mode voltage. The error amplifier circuitry generates currents responsive to a determination that the measured common mode voltage is not equal to the target common mode voltage. The common mode regulator circuitry uses the currents from both the current regulator circuitry and the error amplifier circuitry to modify the common mode voltage at the input of the amplifier circuitry.

In operation, the common mode regulator circuitry modifies both plus and minus input signals at the inputs of the amplifier circuitry by the same current. However, mismatches between components, such as variations resulting from tolerances, of the common mode regulator circuitry create asymmetries between a first current, which modifies the plus input signal, and a second current, which modifies the minus input signal. For example, the first current from the current regulator circuitry and the error amplifier circuitry may differ from a second current from the current regulator circuitry and the error amplifier circuitry. In such examples, ideally, the first and second currents are equal, however component mismatch of from the current regulator circuitry and the error amplifier circuitry result in asymmetries between the first and second currents. In amplifier systems, asymmetries between currents of the plus and minus side input signals increase the total harmonic distortion (THD). THD represents a distortion due to harmonics at different frequencies of analog signals. Signals with relatively high THDs have relatively high voltages at harmonic frequencies. Signals having relatively high THDs result in audible distortions. Asymmetries between signals of the differential pair of analog signals increase the THD.

Relatively high area components (e.g., components occupying a relatively large amount of die space), which have relatively smaller tolerances in comparison to relatively lower area components, reduce asymmetries and attendant THD of a differential pair of analog signals. Alternatively, to reduce package size, designs may be modified to utilize smaller value components. For example, a five percent tolerance of a ten-ohm (Ω) resistor has substantially less variation (i.e., +/−0.5 ohms) in comparison to a five percent tolerance of a one-thousand-ohm resistor (i.e., +/−50 ohms). However, reducing values of components to reduce variations in component values arising from manufacturing tolerances limits performance of the amplifier circuitry. For example, variations in component values resulting from tolerances increases THD.

Some common mode regulator circuitry includes chopping circuitry to reduce asymmetries between signals of a differential pair of signals. The chopping circuitry uses a series of switches to switch between feedback components. Such switching evenly distributes mismatches between signals of a differential pair of signals. For example, the chopping circuitry may include a plurality of switches coupled to the output of the current regulator circuitry and the error amplifier circuitry. In such examples, the switches limit the THD by switching between components forming a first current path and a second current path. However, switching between current paths that have transistors, such as current mirrors in the current regulator circuitry, produces voltage variations. The voltage variations of the transistors are responsive to charge injection by parasitic capacitances (also referred to as Miller capacitances) of the transistors. Such voltage variations may modify the plus and minus input signals responsive to the chopping circuitry allowing the voltage variations to propagate to the inputs of the amplifier circuitry. In amplifier systems, such voltage variations at inputs of the amplifier circuitry may result in audio distortions and increase the THD.

Examples described here include methods and apparatus to regulate an offset of a common mode voltage for amplifier circuitry using mismatch correction circuitry. In some described examples, common mode regulator circuitry includes mismatch correction circuitry including chopping circuitry and isolation components. The chopping circuitry includes a plurality of switches and clock circuitry. The clock circuitry controls the plurality of switches. A first set of switches supply a first current from a first current path of the common mode regulator circuitry to the plus side input of the amplifier circuitry for a first portion of a clock cycle. A second set of switches supply a second current from a second current path of the common mode regulator circuitry to a minus side input of the amplifier circuitry for the first portion of the clock cycle. The first set of switches supply the first current from the first current path of the common mode regulator circuitry to the minus side input of the amplifier circuitry for a second portion of the clock cycle. The second set of switches supply the second current from the second current path of the common mode regulator circuitry to the plus side input of the amplifier circuitry for the second portion of the clock cycle. Advantageously, the switches and clock circuitry of the chopping circuitry reduce mismatch between components of the common mode regulator circuitry by averaging the differences between the first and second currents from the common mode regulator circuitry.

In some described examples, the isolation circuitry of the mismatch correction circuitry includes a series of transistors and control circuitry. The isolation circuitry isolates signals at the inputs of the amplifier circuitry from the common mode regulator circuitry by setting voltages of the first current path and second current path of the common mode regulator circuitry. In some examples, the control circuitry controls a first transistor and a second transistor with a measured common mode voltage of the plus and minus input signals. The first transistor is coupled between the first input of the amplifier circuitry and first set of switches of the chopping circuitry. The second transistor is coupled between the second input of the amplifier circuitry and the second set of switches of the chopping circuitry. In such examples, the measured common mode voltage structures the first and second transistors to operate in a saturation mode. In saturation mode, the first and second transistors set the voltages of common mode input signals of the first and second current paths of common mode regulator circuitry equal to the measured common mode voltage minus the gate-to-source voltage of the transistors. Advantageously, operating the first and second transistors of the mismatch correction circuitry using a measured common mode voltage isolates the first and second inputs of the amplifier circuitry from voltage variations of the common mode regulator circuitry. Advantageously, the mismatch correction circuitry described herein decreases the THD responsive to reducing charge injection during common mode regulation.

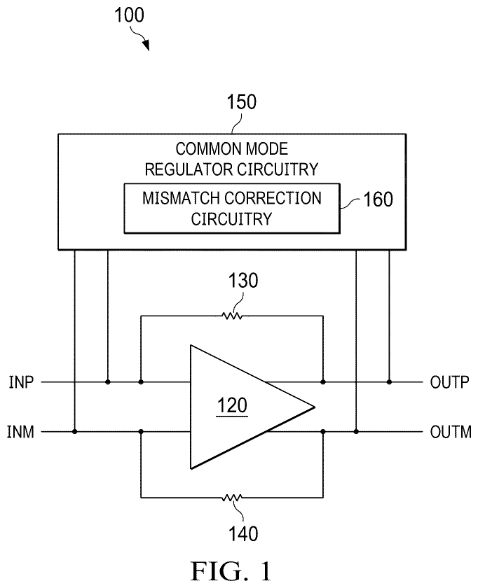

FIG. 1 is a block diagram of an example amplifier system 100. In the example of FIG. 1, the amplifier system 100 includes amplifier circuitry 120, a first resistor 130, a second resistor 140, and common mode regulator circuitry 150. The example common mode regulator circuitry 150 of FIG. 1 includes example mismatch correction circuitry 160. The amplifier system 100 has a first input, a second input, a first output, and a second output. The first and second inputs of the amplifier system 100 are structured to be coupled to an analog signal source, such as an audio source or digital to analog converter (DAC). In the example of FIG. 1, the amplifier system 100 is structured to receive plus and minus input signals (INP, INM) at the first and second inputs of the amplifier system 100. The plus and minus input signals are a pair of signals representing an analog signal to be modulated by the amplifier system 100. The first and second outputs of the amplifier system 100 are structured to be coupled to external circuitry, such as a speaker or signal processing device. In the example of FIG. 1, the amplifier system 100 generates plus and minus output signals (OUTP, OUTM) at the first and second outputs of the amplifier circuitry 100. The plus and minus output signals are a pair of signals representing a modulated version of the plus and minus input signals.

The amplifier circuitry 120 has a first terminal, a second terminal, a third terminal, and a fourth terminal. The first terminal of the amplifier circuitry 120 is coupled to the resistor 130, the common mode regulator circuitry 150, and the first input of the amplifier system 100, which supplies the plus input signal (INP). The second terminal of the amplifier circuitry 120 is coupled to the resistor 140, the common mode regulator circuitry 150, and the second input of the amplifier system 100, which supplies the minus input signal (INM). The third terminal of the amplifier circuitry 120 is coupled to the resistor 130, the common mode regulator circuitry 150, and the first output of the amplifier system 100, which supplies the plus side output signal (OUTP). The fourth terminal of the amplifier circuitry 120 is coupled to the resistor 140, the common mode regulator circuitry 150, and the second output of the amplifier system 100, which supplies the minus output signal (OUTM).

The resistor 130 has a first terminal and a second terminal. The first terminal of the resistor 130 is coupled to the amplifier circuitry 120, the common mode regulator circuitry 150, and the first input of the amplifier system 100, which supplies the plus input signal (INP). The second terminal of the resistor 130 is coupled to the amplifier circuitry 120, the common mode regulator circuitry 150, and the first output of the amplifier system 100, which supplies the plus output signal (OUTP).

The resistor 140 has a first terminal and a second terminal. The first terminal of the resistor 140 is coupled to the amplifier circuitry 120, the common mode regulator circuitry 150, and the second input of the amplifier system 100, which supplies the minus input signal (INM). The second terminal of the resistor 140 is coupled to the amplifier circuitry 120, the common mode regulator circuitry 150, and the second output of the amplifier system 100, which supplies the minus output signal.

The common mode regulator circuitry 150 has a first terminal, a second terminal, a third terminal, and a fourth terminal. The first terminal of the common mode regulator circuitry 150 is coupled to the amplifier circuitry 120, the resistor 130, and the first input of the amplifier system 100, which supplies the plus input signal (INP). The second terminal of the common mode regulator circuitry 150 is coupled to the amplifier circuitry 120, the resistor 140, and the second input of the amplifier system 100, which supplies the minus input signal (INM). The third terminal of the common mode regulator circuitry 150 is coupled to the amplifier circuitry 120, the resistor 130, and the first output of the amplifier system 100, which supplies the plus output signal (OUTP). The fourth terminal of the common mode regulator circuitry 150 is coupled to the amplifier circuitry 120, the resistor 140, and the second output of the amplifier system 100, which supplies the minus output signal (OUTM).

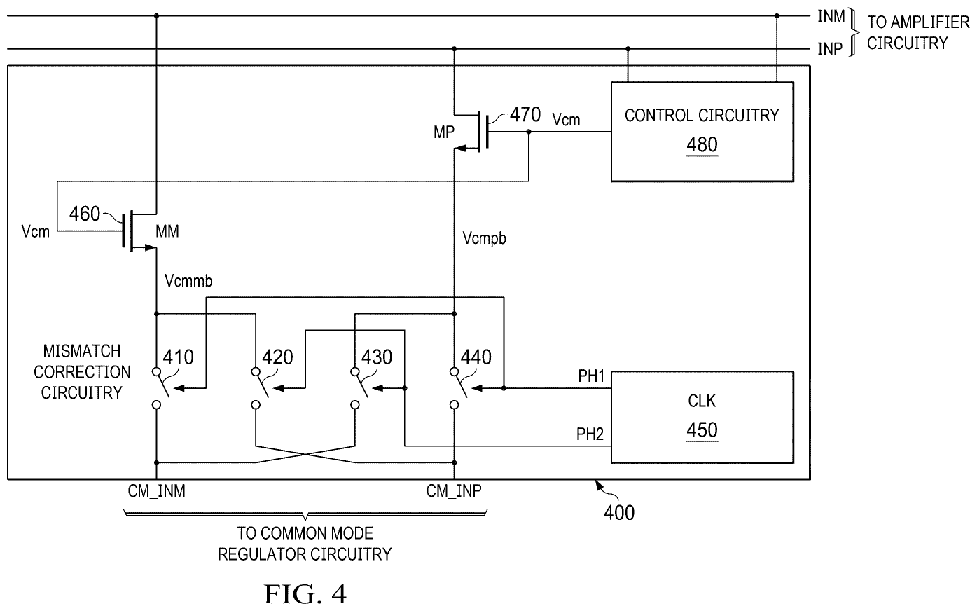

In the example of FIG. 1, the common mode regulator circuitry 150 includes the mismatch correction circuitry 160. The mismatch correction circuitry 160 is structured to be coupled to the first and second inputs of the amplifier system 100, which supply the plus and minus input signals (INP, INM). In some examples, the mismatch correction circuitry 160 is also structured to be coupled to the first and second outputs of the amplifier system 100, which supply the plus and minus output signals (OUTP, OUTM). Examples of the mismatch correction circuitry 160 are illustrated and described in connection with FIGS. 4, 5, 7, and 9, below.

In example operations, the amplifier circuitry 120 receives the plus and minus input signals from an external signal source. The amplifier circuitry 120 at least one of amplifies or modulates the plus and minus input signals to generate the plus and minus output signals. In such example operations, the resistors 130, 140 supply feedback currents to the inputs of the amplifier system 100 to increase the accuracy of the plus and minus output signals.

In example operations, the common mode regulator circuitry 150 regulates a common mode voltage of the plus and minus input signals. In some examples, the common mode regulator circuitry 150 generates first and second compensation currents by mirroring the feedback currents through the resistors 130, 140. The first and second compensation currents are structured to reduce shifts in the common mode voltage resulting from the feedback currents of the resistors 130, 140. Also, the common mode regulator circuitry 150 modifies the first and second compensation currents based on a comparison of the common mode voltage of the plus and minus signals to a target common mode voltage. In such example operations, the mismatch correction circuitry 160 includes circuitry to reduce mismatches between the first and second feedback currents. Also, the mismatch correction circuitry 160 isolates voltage variations that result from switching between supplying the first and second feedback currents to the plus and minus input signals.

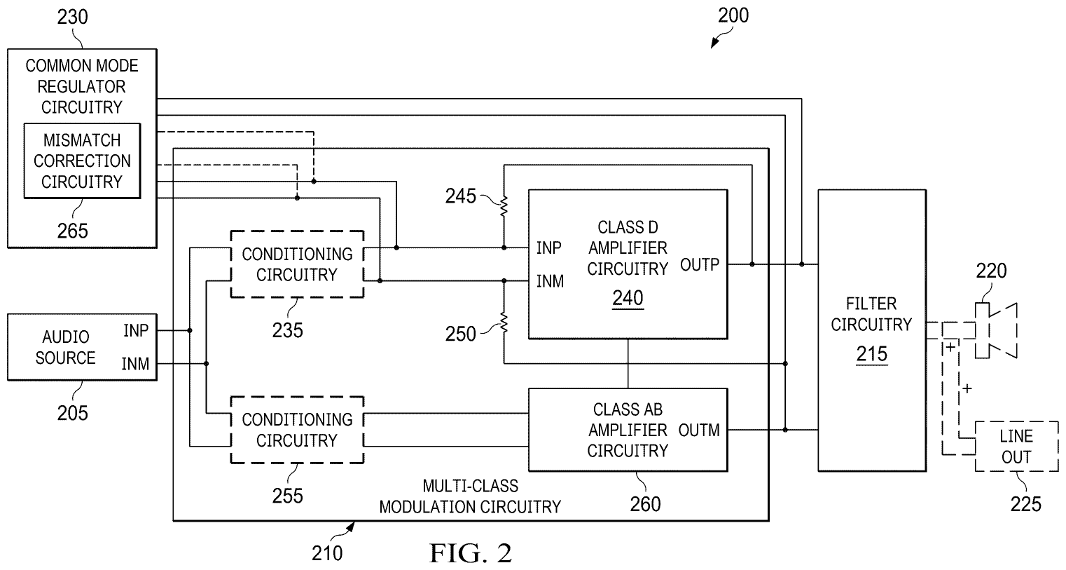

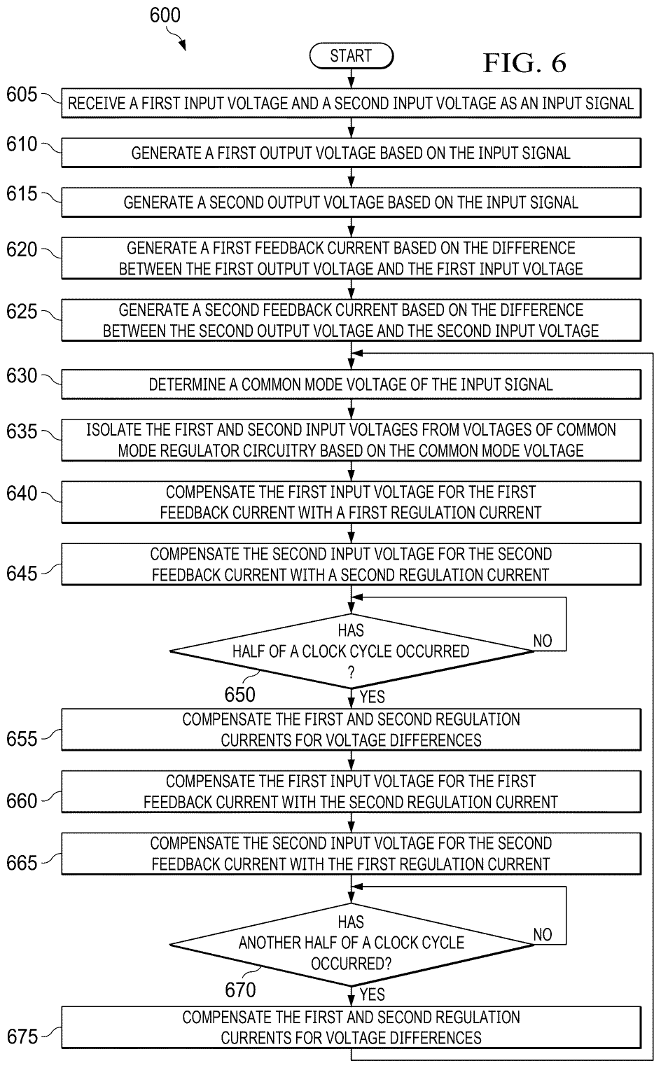

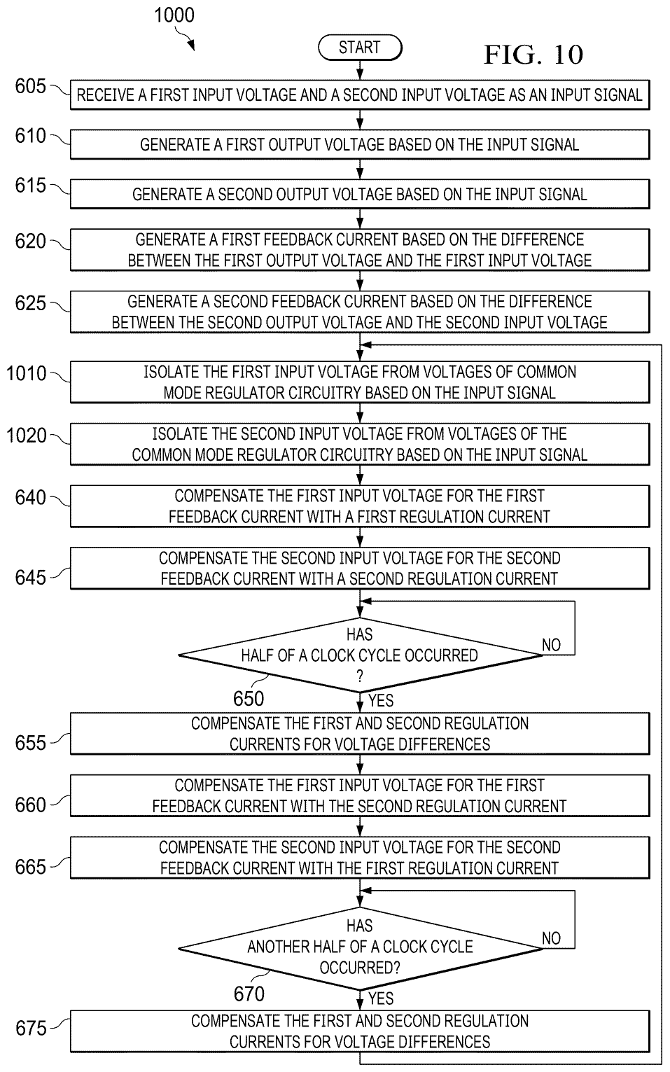

Example operations of the amplifier system 100 are further illustrated and described in connection with FIGS. 6 and 10, below. Also, FIG. 2 illustrates and describes and alternative example of the amplifier system 100, which is structured to implement a modulation technique. Alternatively, the amplifier system 100 may be modified to implement another type of signal modulation.

FIG. 2 is a block diagram of an example audio system 200, which is an example implementation of the amplifier system 100 of FIG. 1. In the example of FIG. 2, the audio system 200 includes an example audio source 205, example multi-class modulation circuitry 210, example filter circuitry 215, an example speaker 220, an example line out port 225, and example common mode regulator circuitry 230. The example multi-class modulation circuitry 210 of FIG. 2 includes first example conditioning circuitry 235, first example amplifier circuitry 240, a first example resistor 245, a second example resistor 250, second example conditioning circuitry 255, and second example amplifier circuitry 260. The example common mode regulator circuitry 230 of FIG. 2 includes example mismatch correction circuitry 265.

In the example of FIG. 2, the audio system 200 is structured to implement single inductor (1L) modulation. Examples of the amplifier circuitry 240, 260 or more generally the multi-class modulation circuitry 210 of FIG. 2, or even more generally the audio system 200 are further illustrated and described in “METHODS AND APPARATUS TO MODULATE SIGNALS USING MULTI-CLASS MODULATION CIRCUITRY” U.S. patent application Ser. No. 18/385,848, which is incorporated by reference in its entirety and is assigned to the assignee of the instant application.

The audio source 205 has a first terminal and a second terminal. The first and second terminals of the audio source 205 are coupled to multi-class modulation circuitry 210. In the example of FIG. 2, the audio source 205 is structured as an analog signal source. In some examples, the audio source 205 is a digital-to-analog converter (DAC). In such examples, the audio source 205 is coupled to digital signal processing circuitry, which supplies digital audio signals.

The multi-class modulation circuitry 210 has a first terminal, a second terminal, a third terminal, a fourth terminal, a fifth terminal, and a sixth terminal. The first and second terminals of the multi-class modulation circuitry 210 are coupled to the audio source 205. The third and fourth terminals of the multi-class modulation circuitry 210 are coupled to the common mode regulator circuitry 230. The fifth and sixth terminals of the multi-class modulation circuitry 210 are coupled to the filter circuitry 215 and the common mode regulator circuitry 230.

The filter circuitry 215 has a first terminal, a second terminal, a third terminal, and a fourth terminal. The first and second terminals of the filter circuitry 215 are coupled to the multi-class modulation circuitry 210 and the common mode regulator circuitry 230. The third and fourth terminals of the filter circuitry 215 may be coupled to one or more of the speaker 220 or the line out port 225.

The speaker 220 has a first terminal and a second terminal. The first and second terminals of the speaker 220 are coupled to the filter circuitry 215 and may be coupled to the line out port 225. The line out port 225 has a first terminal and a second terminal. The first and second terminals of the line out port 225 are coupled to the filter circuitry 215 and may be coupled to the speaker 220.

The common mode regulator circuitry 230 has a first terminal, a second terminal, a third terminal, and a fourth terminal. The first and second terminals of the common mode regulator circuitry 230 are coupled to the multi-class modulation circuitry 210. The third and fourth terminals of the common mode regulator circuitry 230 are coupled to the multi-class modulation circuitry 210 and the filter circuitry 215. In some examples, the common mode regulator circuitry 230 further has a fifth terminal and a sixth terminal. In such examples, the fifth and sixth terminals of the common mode regulator circuitry 230 are coupled to supply terminals of the multi-class modulation circuitry 210.

The conditioning circuitry 235 has a first terminal, a second terminal, a third terminal, and a fourth terminal. The first and second terminals of the conditioning circuitry 235 are coupled to the audio source 205 and the conditioning circuitry 255. The third terminal of the conditioning circuitry 235 is coupled to the common mode regulator circuitry 230, the class D amplifier circuitry 240, and the resistor 245. The fourth terminal of the conditioning circuitry 235 is coupled to the common mode regulator circuitry 230, the class D amplifier circuitry 240, and the resistor 250.

The class D amplifier circuitry 240 has a first terminal, a second terminal, a third terminal, and a fourth terminal. The first terminal of the class D amplifier circuitry 240 is coupled to the common mode regulator circuitry 230, the conditioning circuitry 235, and the resistor 245. The second terminal of the class D amplifier circuitry 240 is coupled to the common mode regulator circuitry 230, the conditioning circuitry 235, and the resistor 250. The third terminal of the class D amplifier circuitry 240 is coupled to the common mode regulator circuitry 230, the filter circuitry 215, and the resistor 245. The fourth terminal of the class D amplifier circuitry 240 is coupled to the common mode regulator circuitry 230, the filter circuitry 215, the class AB amplifier circuitry 260, and the resistor 250.

The resistor 245 has a first terminal and a second terminal. The first terminal of the resistor 245 is coupled to the common mode regulator circuitry 230, the conditioning circuitry 235, and the class D amplifier circuitry 240. The second terminal of the resistor 245 is coupled to the common mode regulator circuitry 230, the filter circuitry 215, and the class D amplifier circuitry 240. In some examples, the resistor 245 is referred to as a feedback resistor (R_{fb}).

The resistor 250 has a first terminal and a second terminal. The first terminal of the resistor 250 is coupled to the common mode regulator circuitry 230, the conditioning circuitry 235, and the class D amplifier circuitry 240. The second terminal of the resistor 250 is coupled to the common mode regulator circuitry 230, the filter circuitry 215, the class D amplifier circuitry 240, and the class AB amplifier circuitry 260. In some examples, the resistor 250 is referred to as a feedback resistor (R_{fb}).

The conditioning circuitry 255 has a first terminal, a second terminal, a third terminal, and a fourth terminal. The first and second terminals of the conditioning circuitry 255 are coupled to the audio source 205 and the conditioning circuitry 235. The third and fourth terminals of the conditioning circuitry 255 are coupled to the class AB amplifier circuitry 260.

The class AB amplifier circuitry 260 has a first terminal, a second terminal, a third terminal, and a fourth terminal. The first and second terminals of the class AB amplifier circuitry 260 are coupled to the conditioning circuitry 255. The third and fourth terminals of the class AB amplifier circuitry 260 are coupled to the common mode regulator circuitry 230, the filter circuitry 215, the class D amplifier circuitry 240, and the resistor 250.

In example operation, the audio source 205 supplies the plus and minus input signals (INP, INM) to multi-class modulation circuitry 210. In the example of FIG. 2, the plus and minus input signals represent an audio signal that, when supplied to the speaker 220, corresponds to audible sound. In some examples, the conditioning circuitry 235, 255 filters the plus and minus input signals to reduce noise. The class D amplifier circuitry 240 receives the plus and minus input signals. The plus input signal of the class D amplifier circuitry 240 includes contributions from feedback currents from the resistor 245 and currents from the common mode regulator circuitry 230. The minus input signal of the class D amplifier circuitry 240 includes contributions from feedback currents from the resistor 250 and currents from the common mode regulator circuitry 230. The class D amplifier circuitry 240 modulates the differential pair of amplifier input signals to generate a plus output signal (OUTP). The class AB amplifier circuitry 260 modulates the plus and minus input signals to generate a minus output signal (OUTM). The filter circuitry 215 supplies an amplified audio signal to the speaker 220 and the line out port 225 by filtering the plus and minus output signals.

In such example operations, the resistors 245, 250 form feedback paths between the inputs of the class D amplifier circuitry 240 and the outputs of the multi-class modulation circuitry 210. The feedback currents through the resistors 245, 250 are proportional to the differences between voltages of the plus and minus input signals and the plus and minus output signals. The common mode regulator circuitry 230 replicates the feedback currents through the resistors 245, 250. In some examples, the common mode regulator circuitry 230 compares the feedback currents to an idle current, which represents the feedback currents during idle operations. When the idle current is greater than the feedback currents, the common mode regulator circuitry 230 supplies a current equal to the idle current minus the feedback currents to the inputs of the class D amplifier circuitry 240. When the feedback currents are greater than the idle current, the common mode regulator circuitry 230 sinks a current equal to the feedback currents minus the idle current from the inputs of the class D amplifier circuitry 240. Advantageously, the common mode regulator circuitry 230 and the mismatch correction circuitry 265 reduce variations in the common mode of the inputs of the class D amplifier circuitry 240 by adjusting currents of the plus and minus input signals of the class D amplifier circuitry 240. Example operations of the common mode regulator circuitry 230 and the mismatch correction circuitry 265 are further illustrated and described in connection with FIGS. 6 and 10, below.

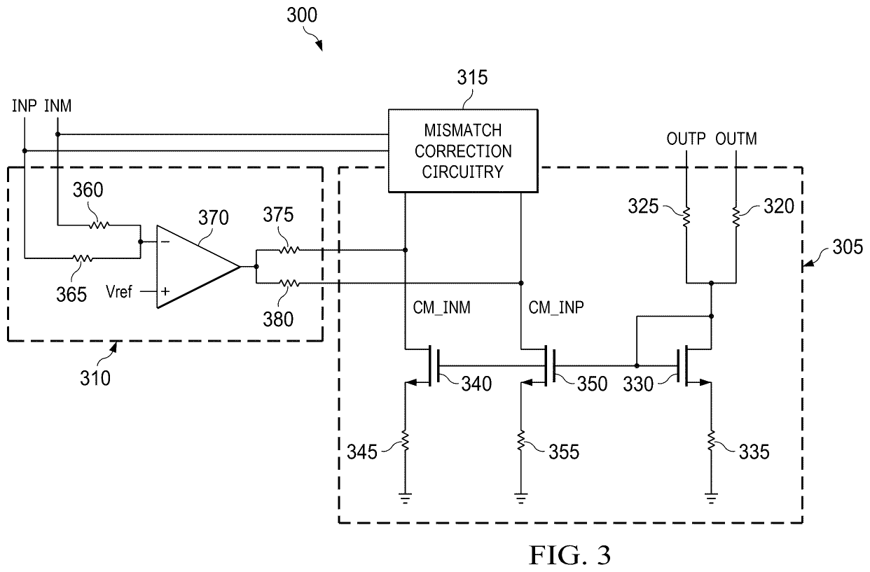

FIG. 3 is a schematic diagram of example common mode regulator circuitry 300, which is an example of the common mode regulator circuitry 150, 230 of FIGS. 1 and 2. In the example of FIG. 3, the common mode regulator circuitry 300 includes current regulator circuitry 305, amplifier circuitry 310, and mismatch correction circuitry 315. The example current regulator circuitry 305 of FIG. 3 includes a first example resistor 320, a second example resistor 325, a first example transistor 330, a third example resistor 335, a second example transistor 340, a fourth example resistor 345, a third example transistor 350, and a fourth example resistor 355. The example amplifier circuitry 310 of FIG. 3 includes a first example resistor 360, a second example resistor 365, an example amplifier 370, a third example resistor 375, and a fourth example resistor 380.

The common mode regulator circuitry 300 has a first input, a second input, a first output and a second output. The first input of the common mode regulator circuitry 300 is structured to be coupled to the amplifier circuitry 120, 240 of FIGS. 1 and 2, which supplies the p-side output signal (OUTP). The second input of the common mode regulator circuitry 300 is structured to be coupled to the amplifier circuitry 120, 260 of FIGS. 1 and 2, which supplies the minus output signal (OUTM). The first output of the common mode regulator circuitry 300 is structured to be coupled to the amplifier circuitry 120, 240, which receives the plus input signal (INP). The second output of the common mode regulator circuitry 300 is structured to be coupled to the amplifier circuitry 120, 240, which receives the minus input signal (INM).

The current regulator circuitry 305 has a first terminal, a second terminal, a third terminal, and a fourth terminal. The first and second terminals of the current regulator circuitry 305 are coupled to the first and second inputs of the common mode regulator circuitry 300, which supply the plus and minus output signals (OUTP, OUTM). The second and third terminals of the current regulator circuitry 305 are coupled to the amplifier circuitry 310 and the mismatch correction circuitry 315.

The amplifier circuitry 310 has a first terminal, a second terminal, a third terminal, and a fourth terminal. The first and second terminals of the amplifier circuitry 310 are coupled to the first and second outputs of the common mode regulator circuitry 300, which supply the plus and minus input signals (INP, INM). The third and fourth terminals of the amplifier circuitry 310 are coupled to the current regulator circuitry 305 and the mismatch correction circuitry 315.

The mismatch correction circuitry 315 has a first terminal, a second terminal, a third terminal and a fourth terminal. The first and second terminals of the mismatch correction circuitry 315 are coupled to the first and second outputs of the common mode regulator circuitry 300, which supply the plus and minus input signals (INP, INM). The third and fourth terminals of the mismatch correction circuitry 315 are coupled to the current regulator circuitry 305 and the amplifier circuitry 310. Examples of the mismatch correction circuitry 315 are further illustrated and described in connection with FIGS. 4, 5, and 7, below.

The resistor 320 has a first terminal and a second terminal. The first terminal of the resistor 320 is coupled to the second input of the common mode regulator circuitry 300, which supplies the minus output signal (OUTM). The second terminal of the resistor 320 is coupled to resistor 325 and the transistors 330, 340, 350.

The resistor 325 has a first terminal and a second terminal. The first terminal of the resistor 325 is coupled to the first input of the common mode regulator circuitry 300, which supplies the plus side output signal (OUTP). The second terminal of the resistor 325 is coupled to the resistor 320 and the transistors 330, 340, 350. In some examples, the resistors 320, 325 have approximately (preferably exactly) equal resistances. In such examples, the resistors 320, 325 are structured as common mode detect circuitry, which generates a common mode voltage between the plus and minus output signals at the first and second inputs of the common mode regulator circuitry 300.

The transistor 330 has a first terminal, a second terminal, and a control terminal. The first and control terminals of the transistor 330 are coupled to the resistors 320, 325 and the transistors 340, 350. The second terminal of the transistor 330 is coupled to the resistor 335. The resistor 335 has a first terminal and a second terminal. The first terminal of the resistor 335 is coupled to the transistor 330. The second terminal of the resistor 335 is coupled to a common terminal, which supplies a common potential (e.g., ground, AVSS, etc.).

The transistor 340 has a first terminal, a second terminal, and a control terminal. The first terminal of the transistor 340 is coupled to the amplifier circuitry 310 and the mismatch circuitry 315. The second terminal of the transistor 340 is coupled to the resistor 345. The control terminal of the transistor 340 is coupled to the resistors 320, 325 and the transistors 330, 350. The resistor 345 has a first terminal and a second terminal. The first terminal of the resistor 345 is coupled to the transistor 340. The second terminal of the resistor 345 is coupled to the common terminal, which supplies the common potential.

The transistor 350 has a first terminal, a second terminal, and a control terminal. The first terminal of the transistor 350 is coupled to the amplifier circuitry 310 and the mismatch correction circuitry 315. The second terminal of the transistor 350 is coupled to the resistor 355. The control terminal of the transistor 350 is coupled to the resistors 320, 325 and the transistors 330, 340. In the example of FIG. 3, the transistors 330, 340, 350 are structured as current mirror circuitry, which uses the transistors 340, 350 to mirror current through the transistor 330. The resistor 355 has a first terminal and a second terminal. The first terminal of the resistor 355 is coupled to the transistor 350. The second terminal of the resistor 355 is coupled to the common terminal, which supplies the common potential.

In the example of FIG. 3, the transistors 330, 340, 350 are n-channel metal-oxide semiconductor field-effect transistors (MOSFETs). Alternatively, the transistors 330, 340, 350 may be n-channel field-effect transistors (FETs), n-channel insulated-gate bipolar transistors (IGBTs), n-channel junction field effect transistors (JFETs), NPN bipolar junction transistors (BJTs) or, with slight modifications, p-type equivalent devices. The transistors 330, 340, 350 may be depletion mode devices, drain-extended devices, enhancement mode devices, natural transistors or other type of device structure transistors. Furthermore, the transistors 330, 340, 350 may be implemented in/over a silicon substrate (Si), a silicon carbide substrate (SiC), a gallium nitride substrate (GaN) or a gallium arsenide substrate (GaAs).

The resistor 360 has a first terminal and a second terminal. The first terminal of the resistor 360 is coupled to the mismatch correction circuitry 315 and the second output of the common mode regulation circuitry, which supplies the minus input signal (INM). The second terminal of the resistor 360 is coupled to the resistor 365 and the amplifier 370. The resistor 365 has a first terminal and a second terminal. The first terminal of the resistor 365 is coupled to the mismatch correction circuitry 315 and the first output of the common mode regulator circuitry 300, which supplies the plus input signal (INP). The second terminal of the resistor 365 is coupled to the resistor 360 and the amplifier 370. In some examples, the resistors 360, 365 have approximately (preferably exactly) equal resistances. In such examples, the resistors 360, 365 are structured as common mode detect circuitry, which generates a common mode voltage between the plus and minus side input signals at the first and second outputs of the common mode regulator circuitry 300.

The amplifier 370 has a first input, a second input, and an output. The first input of the amplifier 370 (also referred to as a non-inverting input) is coupled to the resistors 360, 365. The second input of the amplifier 370 (also referred to as an inverting input) is coupled to a reference terminal, which supplies a reference voltage (Vref). In some examples, the reference voltage is a target common mode voltage of the plus and minus side input signals at the inputs of the amplifier circuitry 120, 240 and the first and second outputs of the common mode regulator circuitry 300. The output of the amplifier 370 is coupled to the resistors 375, 380.

The resistor 375 has a first terminal and a second terminal. The first terminal of the resistor 375 is coupled to the amplifier 370 and the resistor 380. The second terminal of the resistor 375 is coupled to the current regulator circuitry 305 and the mismatch correction circuitry 315. The resistor 380 has a first terminal and a second terminal. The first terminal of the resistor 380 is coupled to the amplifier 370 and the resistor 375. The second terminal of the resistor 380 is coupled to the current regulator circuitry 305 and the mismatch correction circuitry 315.

In example operation, the current regulator circuitry 305 determines the feedback currents through the resistors 130, 140, 245, 250 of FIGS. 1 and 2 responsive to the currents through the resistors 320, 325. The transistors 340, 350 mirror the feedback currents responsive to mirroring the current through the transistor 330. The transistors 340, 350 contribute current to plus and minus common mode signals (CM_INP, CM_INM) at inputs of the mismatch correction circuitry 315 to compensate the plus and minus input signals for the feedback currents.

In example operation, the amplifier circuitry 310 determines a difference between the common mode voltage of the plus and minus input signals and a target common mode voltage responsive to a comparison by the amplifier 370. The resistors 360, 365 set the first input of the amplifier 370 to the common mode voltage of the plus and minus input signals and the reference terminal coupled to the second input of the amplifier circuitry 370 supplies the target common mode voltage. The amplifier circuitry 370 generates an output proportional to the difference between the measured and target common mode voltages. The resistors 375, 380 contribute current to the plus and minus common mode signals at the input of the mismatch correction circuitry 315 to compensate for mismatch between the measured and target common mode voltages.

In example operations, the mismatch correction circuitry 315 regulates a supply of the plus and minus common mode signals to the inputs of the amplifier circuitry 120, 240, 260 to compensate for common mode voltage errors. Advantageously, the mismatch correction circuitry 315 sets voltages of the plus and mins common mode signals to prevent parasitic capacitances of the transistors 340, 350 from generating voltage variations during switching events. Example operations of the common mode regulator circuitry 300 are further illustrated and described in connection with FIG. 6, below.

FIG. 4 is a schematic diagram of example mismatch correction circuitry 400, which is an example of the mismatch correction circuitry 160, 265, 315 of FIGS. 1, 2, and 3. In the example of FIG. 4, the mismatch correction circuitry 400 includes a first switch 410, a second switch 420, a third switch 430, a fourth switch 440, clock circuitry 450, a first transistor 460, a second transistor 470, and control circuitry 480. The mismatch correction circuitry 400 has a first input, a second input, a third input, a fourth input, a first output, and a second output. The first input of the mismatch correction circuitry 400 is structured to be coupled to the transistor 340 of FIG. 3 and the resistor 375 of FIG. 3 or more generally the current regulator circuitry 305 of FIG. 3 and the amplifier circuitry 310 of FIG. 3, which supply the minus common mode signal (CM_INM). The second input of the mismatch correction circuitry 400 is structured to be coupled to the transistor 350 of FIG. 3 and the resistor 380 of FIG. 3 or more generally the current regulator circuitry 305 and the amplifier circuitry 310, which supply the plus common mode signal (CM_INP). The third and fourth inputs and the first and second outputs of the mismatch correction circuitry 400 are structured to be coupled to the amplifier circuitry 120, 240, which supply the plus and minus input signals (INP, INM).

The switch 410 has a first terminal, a second terminal, and a control terminal. The first terminal of the switch 410 is coupled to the switch 420 and the transistor 460. The second terminal of the switch 410 is coupled to the switch 430 and the first input of the mismatch correction circuitry 400, which supplies the minus common mode signal (CM_INM). The control terminal of the switch 410 is coupled to the switch 440 and the clock circuitry 450.

The switch 420 has a first terminal, a second terminal, and a control terminal. The first terminal of the switch 420 is coupled to the switch 410 and the transistor 460. The second terminal of the switch 420 is coupled to the switch 440 and the second input of the mismatch correction circuitry 400, which supplies the minus common mode signal (CM_INM). The control terminal of the switch 420 is coupled to the switch 430 and the clock circuitry 450.

The switch 430 has a first terminal, a second terminal, and a control terminal. The first terminal of the switch 430 is coupled to the switch 440 and the transistor 470. The second terminal of the switch 430 is coupled to the switch 420 and the plus common mode signal (CM_INP). The control terminal of the switch 430 is coupled to the switch 420 and the clock circuitry 450.

The switch 440 has a first terminal, a second terminal, and a control terminal. The first terminal of the switch 440 is coupled to the switch 430 and the transistor 470. The second terminal of the switch 440 is coupled to the switch 420 and the first input of the mismatch correction circuitry 400, which supplies the plus common mode signal (CM_INP). The control terminal of the switch 440 is coupled to the switch 410 and the clock circuitry 450.

The clock circuitry 450 has a first terminal and a second terminal. The first terminal of the clock circuitry 450 is coupled to the switches 410, 440. The second terminal of the clock circuitry 450 is coupled to the switches 420, 430. In the example of FIG. 4, the clock circuitry 450 supplies a first clock signal (PH1) and a second clock signal (PH2) to the switches 410, 420, 430, 440. In such examples, the first clock signal and second clock signal have different phases and non-overlapping pulses.

The transistor 460 has a first terminal, a second terminal, and a control terminal. The first terminal of the transistor 460 is coupled to the first output of the mismatch correction circuitry 400, which supplies the minus input signal (INM). The second terminal of the transistor 460 is coupled to the switches 410, 420. The control terminal of the transistor 460 is coupled to the transistor 470 and the control circuitry 480.

The transistor 470 has a first terminal, a second terminal, and a control terminal. The first terminal of the transistor 470 is coupled to the second output of the mismatch correction circuitry 400, which supplies the plus input signal (INP). The second terminal of the transistor 470 is coupled to the switches 430, 440. The control terminal of the transistor 470 is coupled to the transistor 460 and the control circuitry 480.

In the example of FIG. 4, the transistors 460, 470 are n-channel MOSFETs. Alternatively, the transistors 460, 470 may be n-channel FETs, n-channel IGBTs, n-channel JFETs, NPN BJTs or, with slight modifications, p-type equivalent devices. The transistors 460, 470 may be depletion mode devices, drain-extended devices, enhancement mode devices, natural transistors or other type of device structure transistors. Furthermore, the transistors 460, 470 may be implemented in/over a silicon substrate (Si), a silicon carbide substrate (SiC), a gallium nitride substrate (GaN) or a gallium arsenide substrate (GaAs).

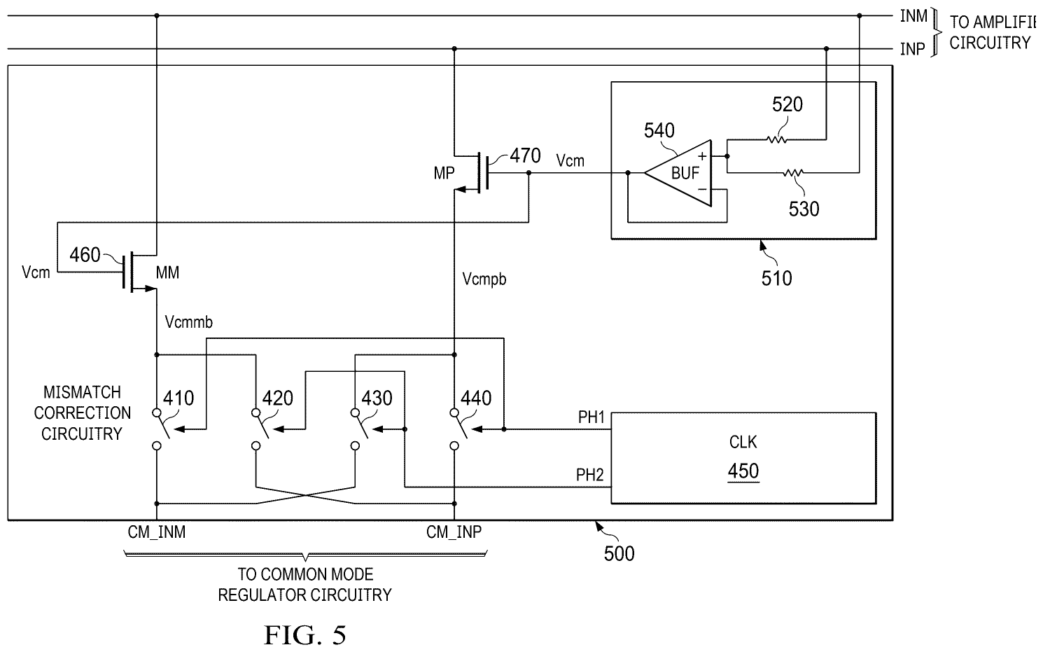

The control circuitry 480 has a first terminal, a second terminal, and a third terminal. The first terminal of the control circuitry 480 is coupled to the third input terminal of the mismatch correction circuitry 400, which supplies the plus side input signal (INP). The second terminal of the control circuitry 480 is coupled to the fourth input terminal of the mismatch correction circuitry 400, which supplies the minus side input signal (INM). The third terminal of the control circuitry 480 is coupled to the transistor 460, 470. An example of the control circuitry 480 is further illustrated and described in connection with FIG. 5, below.

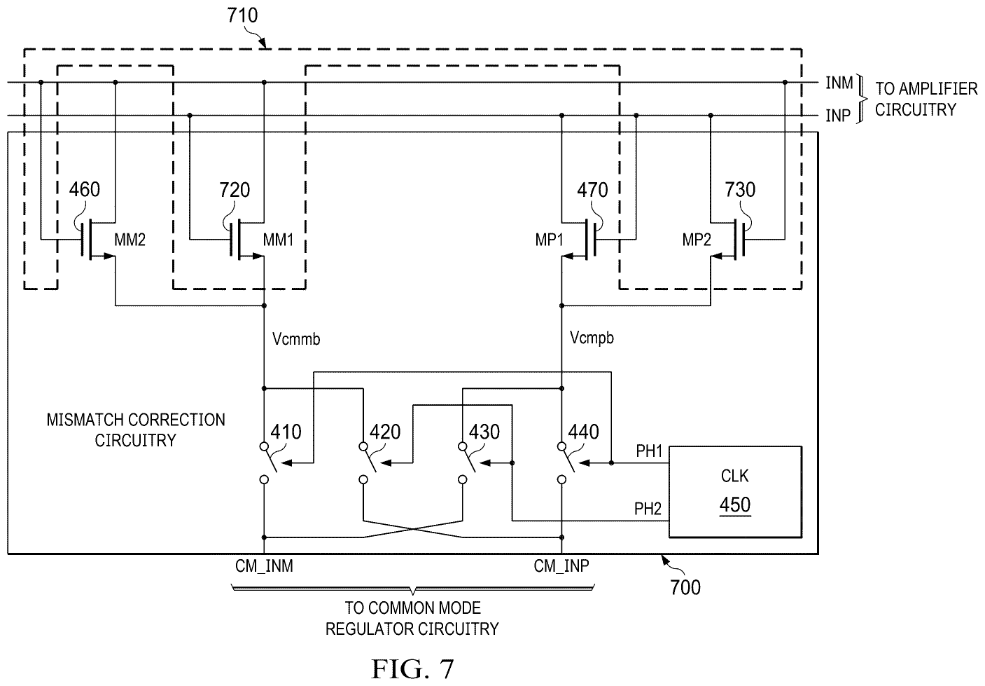

In the example of FIG. 4, the switches 410, 420, 430, 440 are illustrated and described as switches. In some examples, the switches 410, 420, 430, 440 may be implemented or illustrated using transistors having control terminals coupled to the clock circuitry 450. Also, in some examples, the switches 410, 420, 430, 440 and the clock circuitry 450 illustrated as or referred to as chopping circuitry. Examples of the mismatch correction circuitry 400 is illustrated and described in connection with FIGS. 5 and 7, below. Example operations of the mismatch correction circuitry 400 are illustrated and described in connection with FIG. 6, below.

FIG. 5 is a schematic diagram of example mismatch correction circuitry 500, which is another example of the mismatch correction circuitry 160, 265, 315 of FIGS. 1, 2, and 3, including example control circuitry 510, which is an example of the control circuitry 480 of FIG. 1. In the example of FIG. 5, the mismatch correction circuitry 500 includes the switches 410, 420, 430, 440 of FIG. 4, the clock circuitry 450 of FIG. 4, the transistors 460, 470 of FIG. 4, and the control circuitry 510. The example control circuitry 510 of FIG. 5 includes a first example resistor 520, a second example resistor 530, and example buffer circuitry 540.

The mismatch correction circuitry 500 has a first input, a second input, a third input, a fourth input, a first output, and a second output. The first input of the mismatch correction circuitry 500 is structured to be coupled to the transistor 340 of FIG. 3 and the resistor 375 of FIG. 3 or more generally the current regulator circuitry 305 of FIG. 3 and the amplifier circuitry 310 of FIG. 3, which supply the minus common mode signal (CM_INM). The second input of the mismatch correction circuitry 500 is structured to be coupled to the transistor 350 of FIG. 3 and the resistor 380 of FIG. 3 or more generally the current regulator circuitry 305 and the amplifier circuitry 310, which supply the plus common mode signal (CM_INP). The third and fourth inputs and the first and second outputs of the mismatch correction circuitry 500 are structured to be coupled to the amplifier circuitry 120, 240, which supply the plus and minus input signals (INP, INM).

The control circuitry 510 has a first input, a second input, and an output. The first input of the control circuitry 510 is coupled to the first input of the mismatch correction circuitry 500, which supplies the plus input signal. The second input of the control circuitry 510 is coupled to the second input of the mismatch correction circuitry 500, which supplies the minus input signal. The output of the control circuitry 510 is coupled to the transistors 460, 470.

The resistor 520 has a first terminal and a second terminal. The first terminal of the resistor 520 is coupled to the first input of the control circuitry 510, which supplies the plus input signal (INP). The second terminal of the resistor 520 is coupled to the resistor 530 and the buffer circuitry 540.

The resistor 530 has a first terminal and a second terminal. The first terminal of the resistor 530 is coupled to the second input of the control circuitry 510, which supplies the minus input signal (INM). The second terminal of the resistor 520 is coupled to the resistor 520 and the buffer circuitry 540. In some examples, the resistors 520, 530 have approximately (preferably exactly) equal resistances. In such examples, the resistors 520, 530 are structured as common mode detect circuitry, which generates a common mode voltage between the plus and minus input signals at the first and second inputs of the control circuitry 510.

The buffer circuitry 540 has a first input, a second input, and an output. The first input (also referred to as a non-inverting input) of the buffer circuitry 540 is coupled to the resistors 520, 530. The second input (also referred to as an inverting input) and output of the buffer circuitry 540 are coupled to the transistors 460, 470. In some examples, the buffer circuitry 540 is illustrated or described as an amplifier. Example operations of the control circuitry 510 of FIG. 5 are illustrated and described in connection with FIG. 6, below.

FIG. 6 is a flowchart representative of example machine-readable instructions or example operations 600 that may be at least one of executed, instantiated, or performed using an example implementation of the mismatch correction circuitry 160, 265, 315, 400, 500 of FIGS. 1, 2, 3, 4, and 5 or more generally the common mode regulator circuitry 150, 230, 300 of FIGS. 1, 2, and 3. The example operations 600 of FIG. 6 begin at Block 605 at which the amplifier circuitry 120, 240 of FIGS. 1 and 2 receives a first input voltage and a second input voltage as an input signal. (Block 605). In example operations, an analog signal source, such as the audio source 205 of FIG. 2 or a digital to analog converter (DAC), supply a plus input signal (INP) and a minus input signal (INM) to the amplifier circuitry 120, 240, 260 of FIGS. 1 and 2. In such example operations, the plus and minus input signals are a differential pair of input signals having an amplitude defined by a common mode voltage. The common mode voltage is a voltage equidistant from the voltages of the plus and minus input signals. For example, when the plus input signal has a voltage of five volts and the minus input signal has a voltage of negative five volts, the common mode voltage is at zero volts. In another example, when the plus input signal has a voltage of six volts and the minus input signal has a voltage of negative four volts, the common mode voltage is approximately at one volt.

The amplifier circuitry 120, 240 generates a first output voltage based on the input signal. (Block 610). Also, the amplifier circuitry 120, 260 of FIGS. 1 and 2 generates a second output voltage based on the input signal. (Block 615). In some examples, the plus and minus input signals may represent audio signals, analog data signals, etc. In some such examples, the amplifier circuitry 120, 240, 260 at least one of amplifies or modulates the plus and minus input signals to generate a plus output signal (OUTP) and a minus output signal (OUTM). For example, the multi-class modulation circuitry 210 of FIG. 2 is structured to implement 1L modulation, which generates the plus output signal using class D modulation and the minus output signal using class AB modulation. In such an example, the filter circuitry 215 of FIG. 2 averages the plus output signal that when differentially combined with the minus output signal produces and amplified audio signal. In example operations, the amplifier circuitry 120, 240, 260 produce plus and minus output signals having relatively higher voltages in comparison to the plus and minus input signals. Advantageously, the amplifier circuitry 120, 240, 260 allow relatively low power circuitry to generate relatively higher signals.

The resistors 130, 245 of FIGS. 1 and 2 generate a first feedback current based on the difference between the first output voltage and the first input voltage. (Block 620). In example operations, the resistors 130, 245 form a feedback path between a plus output of the amplifier circuitry 120, 240 and a plus side input of the amplifier circuitry 120, 240. In such example operations, the resistors 130, 245 modify the current of the plus input signal responsive to supplying or sinking current through the resistors 130, 245. Advantageously, the feedback path formed by the resistors 130, 245 improves noise immunity and stability of the amplifier circuitry 120, 240.

The resistors 140, 250 of FIGS. 1 and 2 generate a second feedback current based on the difference between the second output voltage and the second input voltage. (Block 625). In example operations, the resistors 140, 250 form a feedback path between a minus output of the amplifier circuitry 120, 260 and a minus input of the amplifier circuitry 120, 240. In such example operations, the resistors 140, 250 modify the current of the minus input signal responsive to supplying or sinking current through the resistors 140, 250. Advantageously, the feedback path formed by the resistors 140, 250 improves noise immunity and stability of the amplifier circuitry 120, 260.

The control circuitry 480, 510 of FIGS. 4 and 5 determines a common mode voltage of the input signal. (Block 630). In example operations, the resistors 520, 530 of FIG. 5 form voltage divider circuitry between the plus and minus input signals. The voltage between the resistors 520, 530 represents a measured common mode voltage (Vcm). In such example operations, the buffer circuitry 540 of FIG. 5 controls the transistors 460, 470 using the measured common mode voltage by buffering the measured common mode voltage from the resistors 520, 530.

The mismatch correction circuitry 160, 265, 315, 400, 500 isolates the first and second input voltages from voltages of the common mode regulator circuitry 150, 230, 300 based on the common mode voltage. (Block 635). In example operations, the control circuitry 480, 510 of FIGS. 4 and 5 controls the transistors 460, 470 of FIGS. 4, and 5 using the measured common mode voltage of the plus and minus input signals. Advantageously, the transistors 460, 470 operate in a saturation region responsive to the control circuitry 480, 510 supplying the measured common mode voltage at the control terminals of the transistors 460, 470. When operating in saturation, the transistors 460, 470 set the voltages of the plus and minus common mode signals (Vcmpb, Vcmmb) equal to the common mode voltage minus the gate-to-source voltage of the transistors 460, 470. In such example operations, the transistors 460, 470 isolate the plus and minus side input signals from voltage variations at the plus and minus common mode signals responsive to the control circuitry 480, 510 using the common mode voltage to operate in saturation mode. Advantageously, the transistors 460, 470 reduce voltage variations at the plus and minus input signals during switching events of the switches 410, 420, 430, 440 of FIG. 4, which are further described below.

The switch 440 of FIG. 4 compensates the first input voltage for the first feedback current with a first regulation current. (Block 640). Also, the switch 410 of FIG. 4 compensates the second input voltage for the second feedback current with a second regulation current. (Block 645). In example operations, the resistors 320, 325 of FIG. 3 mirror feedback currents through the resistors 130, 140, 245, 250 responsive to having the resistance as the resistors 130, 140, 245, 250. In such example operations, the transistors 340, 350 mirror the current through the transistor 330, which is a combination of the feedback currents from the resistors 320, 325. Advantageously, the current flowing through the transistors 340, 350 represent the feedback currents through the resistors 130, 140, 245, 250.

In example operations, the resistors 360, 365 form voltage divider circuitry between the plus and minus input signals. The voltage between the resistors 360, 365 represents a measured common mode voltage of the plus and minus input signals at an inverting input of the amplifier 370 of FIG. 3. In such example operations, the amplifier 370 compares the measured common mode voltage to the reference voltage (Vref), which represents a target common mode voltage. The output of the amplifier 370 is proportional to the difference between the measured common mode voltage and the target common mode voltage. The output voltage of the amplifier 370 sets the current through the resistors 375, 380 of FIG. 3 proportional to the difference between the measured common mode voltage and the target common mode voltage. Advantageously, currents from the transistors 340, 350 compensate for feedback currents and currents from the resistors 375, 380 compensate for common mode mismatch. Advantageously, the currents of the plus and minus common mode signals (CM_INP, CM_INM) can compensate for common mode shifts resulting from mismatches and feedback currents.

In example operations, the clock circuitry 450 of FIGS. 4 and 5 generates the first and second clock signals (PH1, PH2) to control the switches 410, 420, 430, 440. During a first portion, such as a first half of a clock cycle, the clock circuitry 450 structures the first and second clock signals to close the switches 410, 440 and open the switches 420, 430. When closed, the switch 410 supplies currents of the minus common mode signal to the transistor 460 and the switch 440 supplies currents of the plus common mode signal to the transistor 470. In such example operations, the transistor 460 modifies the current of the minus input signal using currents of the minus common mode signal and the transistor 470 modifies the current of the plus input signal using currents of the plus common mode signal.

The clock circuitry 450 of FIG. 4 determines if half a clock cycle has occurred. (Block 650). During the first portion, such as the first half of a clock cycle, the clock circuitry 450 generates the first and second clock signals to close the switches 410, 440 and open the switches 420, 430. If the clock circuitry 450 determines that half a clock cycle has not occurred (e.g., Block 650 returns a result of NO), control proceeds to return to Block 650.

If the clock circuitry 450 determines that half a clock cycle has occurred (e.g., Block 650 returns a result of YES), the transistors 460, 470 of FIG. 4 compensate the first and second regulation currents for voltage differences. (Block 655). In example operations, the transistors 460, 470 operate in a saturation region responsive to the control circuitry 480, 510 supplying the measured common mode voltage at the control terminals of the transistors 460, 470. When in saturation, the transistors 460, 470 set the plus and minus common mode signals (CM_INP, CM_INM) equal to the common mode voltage minus the gate-to-source voltage of the transistors 460, 470. In such example operations, the transistors 460, 470 reduce voltage variations resulting from parasitic capacitances of the transistors 340, 350 of FIG. 3 responsive to the control circuitry 480, 510 using the common mode voltage to operate in saturation mode. Advantageously, using the transistor 460, 470 to set voltages of the plus and minus side common mode input signals compensates for parasitic capacitances of the current regulator circuitry 305 and the amplifier circuitry 310.

The switch 430 compensates the first input voltage for the first feedback current with the second regulation current. (Block 660). Also, the switch 420 compensates the second input voltage for the second feedback current with the first regulation current. (Block 665). In example operations, during the second half of the clock cycle, the clock circuitry 450 structures the first and second clock signals to open the switches 410, 440 and close the switches 420, 430. When closed, the switch 430 supplies currents of the minus common mode signal to the transistor 470 and the switch 420 supplies currents of the plus common mode signal to the transistor 460. In such example operations, the transistor 460 modifies the current of the minus input signal using currents of the plus common mode signal and the transistor 470 modifies the current of the plus input signal using currents of the minus common mode signal. Advantageously, the mismatch correction circuitry 160, 265, 400, 500 averages mismatch (asymmetries) between components of the common mode regulator circuitry 150, 230, 300 responsive to switching between using the plus and minus side common mode input signals to compensate the plus and minus input signals. Advantageously, switching the supply of the plus and minus common mode signals reduces offset resulting from the common mode regulator circuitry 150, 230, 300.

The clock circuitry 450 determines if another half a clock cycle has occurred. (Block 670). During the second half of the clock cycle, the clock circuitry 450 generates the first and second clock signals to open the switches 410, 440 and close the switches 420, 430. If the clock circuitry 450 determines that half a clock cycle has not occurred (e.g., Block 670 returns a result of NO), control proceeds to return to Block 670.

If the clock circuitry 450 determines that half a clock cycle has occurred (e.g., Block 670 returns a result of YES), the transistors 460, 470 compensate the first and second regulation currents for voltage differences. (Block 675). In example operations, the transistors 460, 470 operate in a saturation region responsive to the control circuitry 480, 510 supplying the measured common mode voltage at the control terminals of the transistors 460, 470. When in saturation, the transistors 460, 470 set the plus and minus common mode signals (CM_INP, CM_INM) equal to the common mode voltage minus the gate-to-source voltage of the transistors 460, 470. In such example operations, the transistors 460, 470 reduce voltage variations in the plus and minus input signals that result from parasitic capacitances of the transistors 340, 350 responsive to the control circuitry 480, 510 using the common mode voltage to operate in saturation mode. Advantageously, using the transistor 460, 470 to set voltages of the plus and minus common mode signals compensates for parasitic capacitances of the current regulator circuitry 305 and the amplifier circuitry 310. Control proceeds to return to Block 640.

Example methods are described with reference to the flowchart illustrated in FIG. 6. However, many other methods of implementing the mismatch correction circuitry 160, 265, 315, 400, 500, or more generally, the common mode regulator circuitry 150, 230, 300 of FIGS. 1, 2, and 3 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

FIG. 7 is a schematic diagram of example mismatch correction circuitry 700, which is another example of the mismatch correction circuitry 160, 265, 315, 400, 500 of FIGS. 1, 2, 3, 4, and 5, and example control circuitry 710, which is another example of the control circuitry 480, 510 of FIGS. 4 and 5. In the example of FIG. 7, the mismatch correction circuitry 700 includes the switches 410, 420, 430, 440 of FIGS. 4 and 5, the clock circuitry 450 of FIGS. 4 and 5, the transistors 460, 470 of FIGS. 4 and 5, and the control circuitry 710. The example control circuitry 710 of FIG. 7 includes a first example transistor 720 and a second example transistor 730. The mismatch correction circuitry 700 has a first input, a second input, a third input, a fourth input, a first output, and a second output. The first input of the mismatch correction circuitry 700 is structured to be coupled to the transistor 340 of FIG. 3 and the resistor 375 of FIG. 3 or more generally the current regulator circuitry 305 of FIG. 3 and the amplifier circuitry 310 of FIG. 3, which supply the minus common mode signal (CM_INM). The second input of the mismatch correction circuitry 700 is structured to be coupled to the transistor 350 of FIG. 3 and the resistor 380 of FIG. 3 or more generally the current regulator circuitry 305 and the amplifier circuitry 310, which supply the plus common mode signal (CM_INP). The third and fourth inputs and the first and second outputs of the mismatch correction circuitry 700 are structured to be coupled to the amplifier circuitry 120, 240, which supply the plus and minus input signals (INP, INM).

The control circuitry 710 has a first input, a second input, a first output, a second output, a third output, a fourth output, a fifth output, and a sixth output. The first and second inputs of the control circuitry 710 are coupled to the first and second inputs of the mismatch correction circuitry 700, which supply the plus and minus input signals. The first and second outputs of the control circuitry 710 are coupled to the first and second outputs of the mismatch correction circuitry 700, which supply the plus and minus input signal. The third output of the control circuitry 710 is coupled to the switches 410, 420 and the transistor 460. The fourth output of the control circuitry 710 is coupled to the switches 430, 440 and the transistor 470. The fifth output of the control circuitry 710 is coupled to the control terminal of the transistor 460. The sixth output of the control circuitry 710 is coupled to the control terminal of the transistor 470.

Unlike in the example of FIGS. 4 and 5, the control circuitry 710 couples the control terminal of the transistor 460 to the second input of the mismatch correction circuitry 700, which supplies the minus input signal (INM). Also, the control circuitry 710 couples the control terminal of the transistor 470 to the first input of the mismatch correction circuitry 700, which supplies the plus input signal (INP). In such examples, voltages of the plus and minus input signals control the transistors 460, 470.

The transistor 720 has a first terminal, a second terminal, and a control terminal. The first terminal of the transistor 720 is coupled to the second input of the mismatch correction circuitry 700, which supplies the minus input signal. The second terminal of the transistor 720 is coupled to the switches 410, 420 and the transistor 460. The control terminal of the transistor 720 is coupled to the first input of the mismatch correction circuitry 700, which supplies the plus input signal (INP).

The transistor 730 has a first terminal, a second terminal, and a control terminal. The first terminal of the transistor 730 is coupled to the first input of the mismatch correction circuitry 700, which supplies the plus input signal (INP). The second terminal of the transistor 730 is coupled to the switches 430, 440 and the transistor 470. The control terminal of the transistor 730 is coupled to the second input terminal of the mismatch correction circuitry 700, which supplies the minus input signal (INM).

In the example of FIG. 7, the transistors 460, 470, 720, 730 are n-channel MOSFETs. Alternatively, the transistors 460, 470, 720, 730 may be n-channel FETs, n-channel IGBTs, n-channel JFETs, NPN BJTs or, with slight modifications, p-type equivalent devices. The transistors 460, 470, 720, 730 may be depletion mode devices, drain-extended devices, enhancement mode devices, natural transistors or other type of device structure transistors. Furthermore, the transistors 460, 470, 720, 730 may be implemented in/over a silicon substrate (Si), a silicon carbide substrate (SiC), a gallium nitride substrate (GaN) or a gallium arsenide substrate (GaAs).

In example operation, the transistors 460, 720 are structured to sink current from the minus input signal and the transistors 470, 730 are structured to sink current from the plus input signal. The transistors 460, 720 sense a common mode voltage of the plus and minus input signals responsive to the control terminals of the transistors 460, 720 being coupled to the plus and minus input signals. Advantageously, the common mode voltage of the plus and minus input signals controls the transistors 460, 470, 720, 730 responsive to each transistor pair having control terminals coupled to different ones of the plus and minus input signals. Advantageously, the transistors 460, 470, 720, 730 have a faster response time, lower cost, lower power consumption, and smaller system on chip size in comparison to using the resistors 520, 530 of FIG. 5 and the buffer circuitry 540 of FIG. 5 to control the transistors 460, 470.

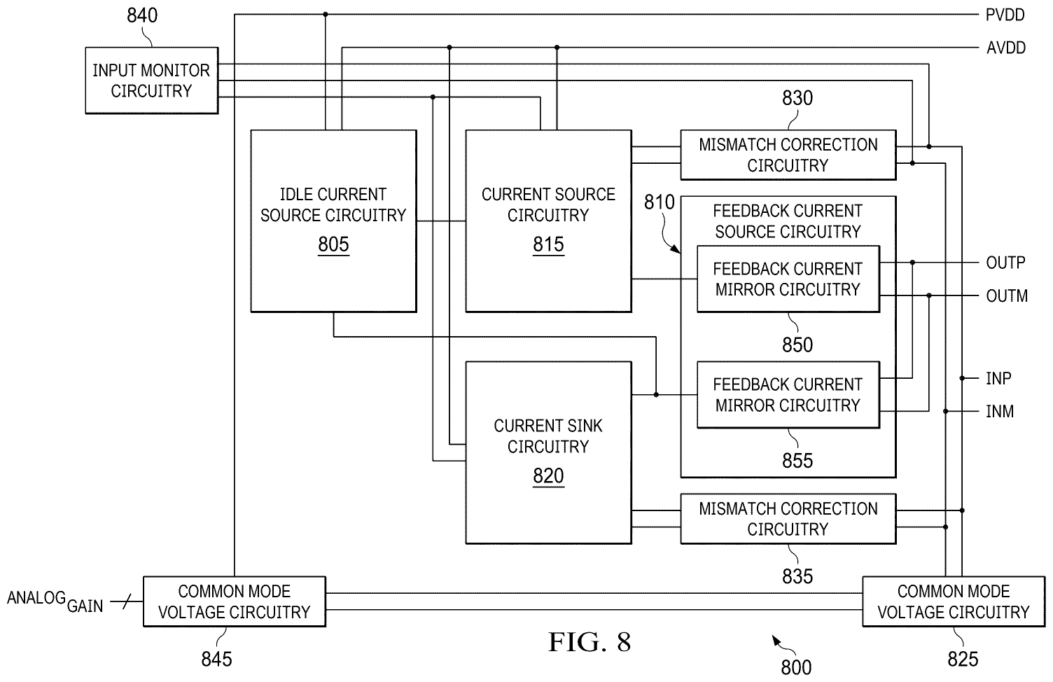

FIG. 8 is a block diagram of example common mode regulator circuitry 800, which is another example of the common mode regulator circuitry 150, 230 of FIGS. 1 and 2. In the example of FIG. 8, the common mode regulator circuitry 800 includes idle current source circuitry 805, feedback current source circuitry 810, current source circuitry 815, current sink circuitry 820, common mode voltage circuitry 825, first mismatch correction circuitry 830, second mismatch correction circuitry 835, input monitor circuitry 840, and common mode voltage control circuitry 845. The feedback current source circuitry 810 of FIG. 8 includes first example feedback current mirror circuitry 850 and second example feedback current mirror circuitry 855.

The common mode regulator circuitry 800 has a first input, a second input, a first output, and a second output. The first input of the common mode regulator circuitry 800 is structured to be coupled to the amplifier circuitry 120, 240 of FIGS. 1 and 2, which supplies the plus output signal (OUTP). The second input of the common mode regulator circuitry 800 is structured to be coupled to the amplifier circuitry 120, 260 of FIGS. 1 and 2, which supplies the minus output signal (OUTM). The first and second outputs of the common mode regulator circuitry 800 are coupled to the amplifier circuitry 120, 240, which receive the plus and minus input signals (INP, INM). In some examples, the common mode regulator circuitry 800 further has an input supply terminal and an output supply terminal, which are coupled to an input supply voltage (AVDD) and an output supply voltage (PVDD). The input supply voltage represents voltages of the plus and minus input signals. The output supply voltage represents voltages of the plus and minus output signals.

The idle current source circuitry 805 has a first terminal, a second terminal, a third terminal, and a fourth terminal. The first terminal of the idle current source circuitry 805 is coupled to the input supply terminal, which supplies the input supply voltage (AVDD). The second terminal of the idle current source circuitry 805 is coupled to the output supply terminal, which supplies the output supply voltage (PVDD). The third terminal of the idle current source circuitry 805 is coupled to the current source circuitry 815. The fourth terminal of the idle current source circuitry 805 is coupled to the feedback current source circuitry 810 and the current sink circuitry 820.

The feedback current source circuitry 810 has a first terminal, a second terminal, a third terminal, a fourth terminal, and a fifth terminal. The first terminal of the feedback current source circuitry 810 is coupled to the first output of the common mode regulator circuitry 800, which supplies the plus side output signal (OUTP). The second terminal of the feedback current source circuitry 810 is coupled to the second output of the common mode regulator circuitry 800, which supplies the minus side output signal (OUTM). The third terminal of the feedback current source circuitry 810 is coupled to the current source circuitry 815. The fourth terminal of the feedback current source circuitry 810 is coupled to the idle current source circuitry 805 and the current sink circuitry 820. The fifth terminal of the feedback current source circuitry 810 is coupled to the current sink circuitry 820.

The current source circuitry 815 has a first terminal, a second terminal, a third terminal, a fourth terminal, and a fifth terminal. The first terminal of the current source circuitry 815 is coupled to the input supply terminal, which supplies the input supply voltage. The second terminal of the current source circuitry 815 is coupled to the idle current source circuitry 805. The third terminal of the current source circuitry 815 is coupled to the current sink circuitry 820 and the input monitor circuitry 840. The fourth and fifth terminals of the current source circuitry 815 are coupled to the mismatch correction circuitry 830.

The current sink circuitry 820 has a first terminal, a second terminal, a third terminal, a fourth terminal, and a fifth terminal. The first terminal of the current sink circuitry 820 is coupled to the input supply terminal, which supplies the input supply voltage. The second terminal of the current sink circuitry 820 is coupled to the idle current source circuitry 805 and the feedback current source circuitry 810. The third terminal of the current sink circuitry 820 is coupled to the current source circuitry 815 and the input monitor circuitry 840. The fourth and fifth terminals of the current sink circuitry 820 are coupled to the mismatch correction circuitry 835.

The common mode voltage circuitry 825 has a first terminal, a second terminal, a third terminal, and a fourth terminal. The first terminal of the common mode voltage circuitry 825 is coupled to the mismatch correction circuitry 830, 835 and the first output of the common mode regulator circuitry 800, which supplies the plus side input signal. The second terminal of the common mode voltage circuitry 825 is coupled to the mismatch correction circuitry 830, 835 and the second output of the common mode regulator circuitry 800, which supplies the minus side input signal. The third and fourth terminals of the common mode voltage circuitry 825 are coupled to the common mode voltage control circuitry 845. In some examples, the common mode voltage circuitry 825 has any number of terminals coupled to the common mode voltage control circuitry 845.

The mismatch correction circuitry 830 has a first terminal, a second terminal, a third terminal, and a fourth terminal. The first and second terminals of the mismatch correction circuitry 830 are coupled to the current source circuitry 815. The third and fourth terminals of the mismatch correction circuitry 830 are coupled to the common mode voltage circuitry 825, the mismatch correction circuitry 835, the input monitor circuitry 840, and the first and second outputs of the common mode regulator circuitry 800, which supplies the plus and minus side input signals (INP, INM).

The mismatch correction circuitry 835 has a first terminal, a second terminal, a third terminal, and a fourth terminal. The first and second terminals of the mismatch correction circuitry 835 are coupled to the current sink circuitry 820. The third and fourth terminals of the mismatch correction circuitry 835 are coupled to the common mode voltage circuitry 825, the mismatch correction circuitry 830, the input monitor circuitry 840, and the first and second outputs of the common mode regulator circuitry 800, which supplies the plus and minus side input signals (INP, INM).

The input monitor circuitry 840 has a first terminal, a second terminal, and a third terminal. The first terminal of the input monitor circuitry 840 is coupled to the first output of the common mode regulator circuitry 800, which supplies the plus side input signal (INP). The second terminal of the input monitor circuitry 840 is coupled to the second output of the common mode regulator circuitry 800, which supplies the minus side input signal (INM). The third terminal of the input monitor circuitry 840 is coupled to the current source circuitry 815 and the current sink circuitry 820.

The common mode voltage control circuitry 845 has a first terminal, a second terminal, a third terminal, and a fourth terminal. The first terminal of the common mode voltage control circuitry 845 is coupled to the output supply terminal, which supplies the output supply voltage. The second and third terminals of the common mode voltage control circuitry 845 are coupled to the common mode voltage circuitry 825. The fourth terminal of the common mode voltage control circuitry 845 is coupled to an analog gain terminal, which supplies an indication of the analog gain of the amplifier circuitry 120, 240. In some examples, the common mode voltage control circuitry 845 is coupled to a BUS, which supplies the analog gain. In other examples, the common mode voltage control circuitry 845 is coupled to a register, which sets the analog gain.

The feedback current mirror circuitry 850 has a first terminal, a second terminal, and a third terminal. The first terminal of the feedback current mirror circuitry 850 is coupled to the first input of the common mode regulator circuitry 800, which supplies the plus side output signal. The second terminal of the feedback current mirror circuitry 850 is coupled to the second input of the common mode regulator circuitry 800, which supplies the minus side output signal. The third terminal of the feedback current mirror circuitry 850 is coupled to the current source circuitry 815.

The feedback current mirror circuitry 855 has a first terminal, a second terminal, and a third terminal. The first terminal of the feedback current mirror circuitry 855 is coupled to the first input of the common mode regulator circuitry 800, which supplies the plus side output signal. The second terminal of the feedback current mirror circuitry 855 is coupled to the second input of the common mode regulator circuitry 800, which supplies the minus side output signal. The third terminal of the feedback current mirror circuitry 855 is coupled to the idle current source circuitry 805 and the current sink circuitry 820.

Examples of the idle current source circuitry 805, the feedback current source circuitry 810, the current source circuitry 815, the current sink circuitry 820, the common mode voltage circuitry 825, the input monitor circuitry 840, the common mode voltage control circuitry 845, the feedback current mirror circuitry 850, and the feedback current mirror circuitry 855 are further illustrated and described in “METHODS AND APPARATUS TO REGULATE A COMMON MODE VOLTAGE OF ANAMPLIFIER” U.S. patent application Ser. No. 18/642,427, which is incorporated by reference in its entirety and is assigned to the assignee of the instant application.

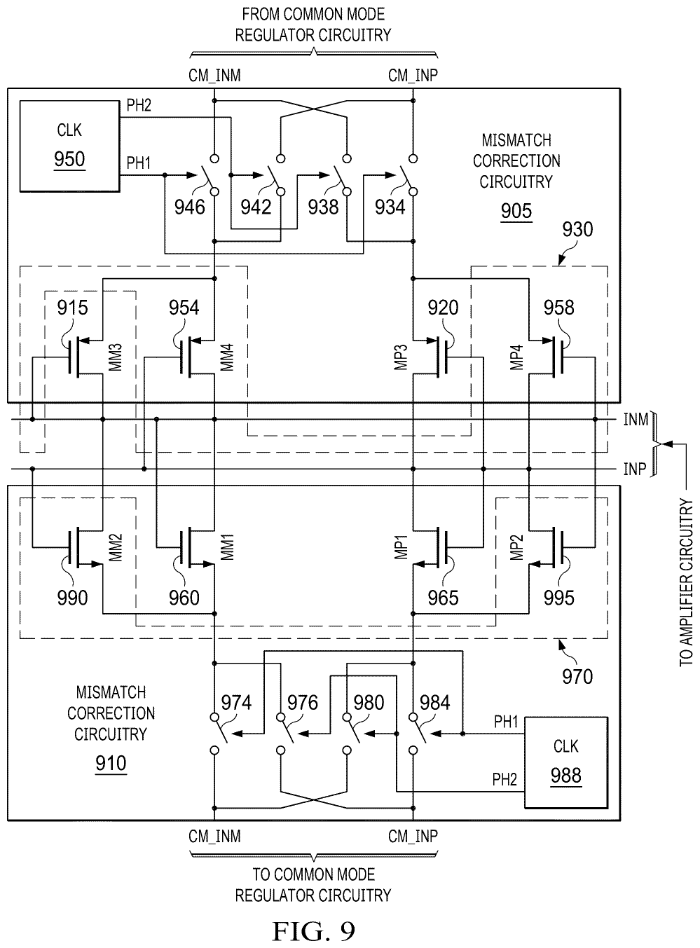

FIG. 9 is a schematic diagram of first mismatch correction circuitry 905, which is an example of the mismatch correction circuitry 830 of FIG. 8, and second mismatch correction circuitry 910, which is an example of the mismatch correction circuitry 835 of FIG. 8. The example mismatch correction circuitry 905 of FIG. 9 includes a first example transistor 915, a second example transistor 920, example control circuitry 930, a first example switch 934, a second example switch 938, a third example switch 942, a fourth example switch 946 and example clock circuitry 950. The example control circuitry 930 of FIG. 9 includes a first example transistor 954 and a second example transistor 958. The example mismatch correction circuitry 910 of FIG. 9 includes a first example transistor 960, a second example transistor 965, example control circuitry 970, a first example switch 974, a second example switch 976, a third example switch 980, a fourth example switch 984, and example clock circuitry 988. The example control circuitry 970 includes a first example transistor 990 and a second example transistor 995.

The mismatch correction circuitry 905 has a first input, a second input, a third input, a fourth input, a first output, and a second output. The first input of the mismatch correction circuitry 905 is structured to be coupled to the current source circuitry 815 of FIG. 8, which supplies the plus common mode signal (CM_INP). The second input of the mismatch correction circuitry 905 is structured to be coupled to current source circuitry 815, which supplies the plus common mode signal (CM_INM). The third and fourth inputs and the first and second outputs of the mismatch correction circuitry 905 are structured to be coupled to the amplifier circuitry 120, 240, which supply the plus and minus input signals (INP, INM).

The mismatch correction circuitry 910 has a first input, a second input, a third input, a fourth input, a first output, and a second output. The first input of the mismatch correction circuitry 910 is structured to be coupled to the current sink circuitry 820 of FIG. 8, which supplies the plus common mode signal (CM_INP). The second input of the mismatch correction circuitry 910 is structured to be coupled to current sink circuitry 820, which supplies the plus common mode signal (CM_INM). The third and fourth inputs and the first and second outputs of the mismatch correction circuitry 910 are structured to be coupled to the amplifier circuitry 120, 240, which supply the plus and minus input signals (INP, INM).

The transistor 915 has a first terminal, a second terminal, and a control terminal. The first terminal of the transistor 915 is coupled to the switches 942, 946 and the transistor 954. The second terminal of the transistor 915 is coupled to the second output of the mismatch correction circuitry 905, which supplies the minus input signal (INM). The control terminal of the transistor 915 is coupled to the control circuitry 930 and the fourth input of the mismatch correction circuitry 905, which supplies the minus input signal (INM).

The transistor 920 has a first terminal, a second terminal, and a control terminal. The first terminal of the transistor 920 is coupled to the switches 934, 938 and the transistor 958. The second terminal of the transistor 920 is coupled to the first output of the mismatch correction circuitry 905, which supplies the plus input signal (INP). The control terminal of the transistor 920 is coupled to the control circuitry 930 and the third input of the mismatch correction circuitry 905, which supplies the plus input signal (INP).

The control circuitry 930 has a first terminal, a second terminal, a third terminal, a third terminal, a fourth terminal, a fifth terminal, and a sixth terminal. The first terminal of the control circuitry 930 is coupled to the transistor 915 and the switches 942, 946. The second terminal of the control circuitry 930 is coupled to the transistor 920 and the switches 934, 938. The third terminal of the control circuitry 930 is coupled to the control terminal of the transistor 915 and the fourth input of the mismatch correction circuitry 905, which supplies the minus input signal (INM). The fourth terminal of the control circuitry 930 is coupled to the control terminal of the transistor 920 and the third input of the mismatch correction circuitry 905, which supplies the plus input signal (INP). The fifth terminal of the control circuitry 930 is coupled to the third input and first output of the mismatch correction circuitry 905, which supplies the plus input signal (INP). The sixth terminal of the control circuitry 930 is coupled to the fourth input and second output of the mismatch correction circuitry 905, which supplies the minus input signal (INM).

The switch 934 has a first terminal, a second terminal, and a control terminal. The first terminal of the switch 934 is coupled to the first input of the mismatch correction circuitry 905, which supplies the plus common mode signal (CM_INP). The second terminal of the switch 934 is coupled to the transistors 920, 958 and the switch 938. The control terminal of the switch 934 is coupled to the switch 946 and the clock circuitry 950.

The switch 938 has a first terminal, a second terminal, and a control terminal. The first terminal of the switch 938 is coupled to the second input of the mismatch correction circuitry 905, which supplies the minus common mode signal (CM_INM). The second terminal of the switch 938 is coupled to the transistors 920, 958 and the switch 934. The control terminal of the switch 938 is coupled to the switch 942 and the clock circuitry 950.

The switch 942 has a first terminal, a second terminal, and a control terminal. The first terminal of the switch 942 is coupled to the first input of the mismatch correction circuitry 905, which supplies the plus common mode signal (CM_INP). The second terminal of the switch 942 is coupled to the transistors 915, 954 and the switch 946. The control terminal of the switch 942 is coupled to the switch 938 and the clock circuitry 950.

The switch 946 has a first terminal, a second terminal, and a control terminal. The first terminal of the switch 946 is coupled to the second input of the mismatch correction circuitry 905, which supplies the side common mode signal (CM_INM). The second terminal of the switch 946 is coupled to the transistors 915, 954 and the switch 942. The control terminal of the switch 946 is coupled to the switch 934 and the clock circuitry 950.

The clock circuitry 950 has a first terminal and a second terminal. The first terminal of the clock circuitry 950 is coupled to the switches 934, 946. The second terminal of the clock circuitry 950 is coupled to the switches 938, 342. In the example of FIG. 9, the clock circuitry 950 supplies a first clock signal (PH1) and a second clock signal (PH2) to the switches 934, 938, 942, 946. In such examples, the first clock signal and second clock signal have different phases and non-overlapping pulses.

The transistor 954 has a first terminal, a second terminal, and a control terminal. The first terminal of the transistor 954 is coupled to the transistor 915 and the switches 942, 946. The second terminal of the transistor 954 is coupled to the second output of the mismatch correction circuitry 905, which supplies the minus input signal (INM). The control terminal of the transistor 954 is coupled to the third input of the mismatch correction circuitry 905, which supplies the plus input signal (INP).

The transistor 958 has a first terminal, a second terminal, and a control terminal. The first terminal of the transistor 958 is coupled to the transistor 920 and the switches 934, 938. The second terminal of the transistor 958 is coupled to the first output of the mismatch correction circuitry 905, which supplies the plus input signal (INP). The control terminal of the transistor 958 is coupled to the fourth input of the mismatch correction circuitry 905, which supplies the minus input signal (INM).

The transistor 960 has a first terminal, a second terminal, and a control terminal. The first terminal of the transistor 960 is coupled to the switches 974, 976 and the transistor 990. The second terminal of the transistor 960 is coupled to the second output of the mismatch correction circuitry 910, which supplies the minus input signal (INM). The control terminal of the transistor 960 is coupled to the control circuitry 970 and the fourth input of the mismatch correction circuitry 910, which supplies the minus input signal (INM).

The transistor 965 has a first terminal, a second terminal, and a control terminal. The first terminal of the transistor 965 is coupled to the switches 980, 984 and the transistor 995. The second terminal of the transistor 965 is coupled to the first output of the mismatch correction circuitry 910, which supplies the plus input signal (INP). The control terminal of the transistor 965 is coupled to the control circuitry 970 and the third input of the mismatch correction circuitry 910, which supplies the plus input signal (INP).

The control circuitry 970 has a first terminal, a second terminal, a third terminal, a third terminal, a fourth terminal, a fifth terminal, and a sixth terminal. The first terminal of the control circuitry 970 is coupled to the transistor 960 and the switches 974, 976. The second terminal of the control circuitry 970 is coupled to the transistor 965 and the switches 980, 984. The third terminal of the control circuitry 970 is coupled to the control terminal of the transistor 960 and the fourth input of the mismatch correction circuitry 910, which supplies the minus input signal (INM). The fourth terminal of the control circuitry 970 is coupled to the control terminal of the transistor 965 and the third input of the mismatch correction circuitry 910, which supplies the plus input signal (INP). The fifth terminal of the control circuitry 970 is coupled to the third input and first output of the mismatch correction circuitry 910, which supplies the plus input signal (INP). The sixth terminal of the control circuitry 970 is coupled to the fourth input and second output of the mismatch correction circuitry 910, which supplies the minus input signal (INM).

The switch 974 has a first terminal, a second terminal, and a control terminal. The first terminal of the switch 974 is coupled to the second input of the mismatch correction circuitry 910, which supplies the minus common mode signal (CM_INM). The second terminal of the switch 974 is coupled to the transistors 960, 990 and the switch 976. The control terminal of the switch 974 is coupled to the switch 984 and the clock circuitry 988.

The switch 976 has a first terminal, a second terminal, and a control terminal. The first terminal of the switch 976 is coupled to the first input of the mismatch correction circuitry 910, which supplies the plus common mode signal (CM_INP). The second terminal of the switch 976 is coupled to the transistors 960, 990 and the switch 974. The control terminal of the switch 976 is coupled to the switch 980 and the clock circuitry 988.

The switch 980 has a first terminal, a second terminal, and a control terminal. The first terminal of the switch 980 is coupled to the second input of the mismatch correction circuitry 910, which supplies the minus common mode signal (CM_INM). The second terminal of the switch 980 is coupled to the transistors 965, 995 and the switch 984. The control terminal of the switch 980 is coupled to the switch 976 and the clock circuitry 988.

The switch 984 has a first terminal, a second terminal, and a control terminal. The first terminal of the switch 984 is coupled to the first input of the mismatch correction circuitry 910, which supplies the plus common mode signal (CM_INP). The second terminal of the switch 984 is coupled to the transistors 965, 995 and the switch 980. The control terminal of the switch 984 is coupled to the switch 974 and the clock circuitry 988.

The clock circuitry 988 has a first terminal and a second terminal. The first terminal of the clock circuitry 988 is coupled to the switches 974, 984. The second terminal of the clock circuitry 988 is coupled to the switches 976, 980. In the example of FIG. 9, the clock circuitry 988 supplies a first clock signal (PH1) and a second clock signal (PH2) to the switches 974, 976, 980, 984. In such examples, the first clock signal and second clock signal have different phases and non-overlapping pulses.

The transistor 990 has a first terminal, a second terminal, and a control terminal. The first terminal of the transistor 990 is coupled to the transistor 960 and the switches 974, 976. The second terminal of the transistor 990 is coupled to the second output of the mismatch correction circuitry 910, which supplies the minus input signal (INM). The control terminal of the transistor 990 is coupled to the third input of the mismatch correction circuitry 910, which supplies the plus input signal (INP).

The transistor 995 has a first terminal, a second terminal, and a control terminal. The first terminal of the transistor 995 is coupled to the transistor 965 and the switches 980, 984. The second terminal of the transistor 995 is coupled to the first output of the mismatch correction circuitry 910, which supplies the plus input signal (INP). The control terminal of the transistor 995 is coupled to the fourth input of the mismatch correction circuitry 910, which supplies the minus input signal (INM).

In the example of FIG. 9, the transistors 960, 965, 990, 995 are n-channel MOSFETs. Alternatively, the transistors 960, 965, 990, 995 may be n-channel FETs, n-channel IGBTs, n-channel JFETs, NPN BJTs or, with slight modifications, p-type equivalent devices. In the example of FIG. 9, the transistors 915, 920, 954, 958 are p-channel MOSFETs. Alternatively, the transistors 915, 920, 954, 958 may be p-channel FETs, p-channel IGBTs, p-channel JFETs, PNP BJTs, or, with slight modifications, N-type equivalent devices. The transistors 915, 920, 954, 958, 960, 965, 990, 995 may be depletion mode devices, drain-extended devices, enhancement mode devices, natural transistors or other type of device structure transistors. Furthermore, the transistors 915, 920, 954, 958, 960, 965, 990, 995 may be implemented in/over a silicon substrate (Si), a silicon carbide substrate (SiC), a gallium nitride substrate (GaN) or a gallium arsenide substrate (GaAs).

FIG. 10 is a flowchart representative of example machine-readable instructions or example operations 1000 that may be at least one of executed, instantiated, or performed using an example implementation of the mismatch correction circuitry 160, 265, 700, 830, 835, 905, 910 of FIGS. 7, 8, and 9 or more generally the common mode regulator circuitry 150, 230, 800 of FIGS. 1, 2, 3, and 8. The example operations 1000 begin with the operations of Blocks 605, 610, 615, 620, 625 of FIG. 6, above. In such example operations, the amplifier circuitry 120, 240, 260 are structured to generate plus and minus output signals responsive to plus and minus side input signals. Control proceeds to Block 1010.

The mismatch correction circuitry 160, 265, 315, 700, 830, 835, 905, 910 of FIGS. 1, 2, 3, 7, 8, and 9 isolate the first input voltage from voltages of the common mode regulator circuitry based on the input signal. (Block 1010). In example operations, the control circuitry 710, 930, 970 of FIGS. 7 and 9 controls the transistors 470, 920, 965 of FIGS. 7 and 9 with the plus side input signal. Also, the control circuitry 710, 930, 970 controls the transistors 730, 958, 995 of FIGS. 7 and 9 with the minus side input signal. In such example operations, the transistors 470, 730, 920, 958, 965, 995 couple the switches 430, 440, 934, 938, 980, 984 of FIGS. 7 and 9 to the input of the amplifier circuitry 120, 240, 260, which receives the plus side input signals.

Advantageously, the transistors 470, 730, 920, 958, 965, 995 sense the common mode voltage of the plus and minus input signals responsive to the plus side input signal controlling the transistors 470, 920, 965 and the minus input signal controlling the transistors 730, 958, 995. Advantageously, the common mode of the plus and minus input signals operates the transistors 470, 730, 920, 958, 965, 995 in a saturation mode. When operating in saturation, the transistors 470, 730, 920, 958, 965, 995 set the plus and minus common mode signals (CM_INP, CM_INM) equal to the common mode voltage minus the gate-to-source voltage of the transistors 470, 730, 920, 958, 965, 995. In such example operations, the transistors 470, 730, 920, 958, 965, 995 isolate the side input signal from voltage variations at the plus and minus common mode signals responsive to the control circuitry 710, 930, 970 using the common mode voltage to operate in saturation mode. Advantageously, the transistors 470, 730, 920, 958, 965, 995 reduce voltage variations at the plus input signal during switching events of the switches 430, 440, 934, 938, 980, 984.

The mismatch correction circuitry 160, 265, 315, 700, 830, 835, 905, 910 isolate the second input voltage from voltages of the common mode regulator circuitry based on the input signal. (Block 1020). In example operations, the control circuitry 710, 930, 970 controls the transistors 460, 915, 960 of FIGS. 7 and 9 with the minus side input signal. Also, the control circuitry 710, 930, 970 controls the transistors 720, 954, 990 of FIGS. 7 and 9 with the plus side input signal. In such example operations, the transistors 460, 720, 915, 954, 960, 990 couple the switches 410, 420, 942, 946, 974, 976 of FIGS. 7 and 9 to the input of the amplifier circuitry 120, 240, 260, which receives the minus input signal.

Advantageously, the transistors 460, 720, 915, 954, 960, 990 sense the common mode voltage of the plus and minus input signals responsive to the minus input signal controlling the transistors 460, 915, 960 and the plus input signal controlling the transistors 720, 954, 990. Advantageously, the common mode of the plus and minus input signals operates the transistors 460, 720, 915, 954, 960, 990 in a saturation mode. When operating in saturation, the transistors 460, 720, 915, 954, 960, 990 set the plus and minus common mode signals (CM_INP, CM_INM) equal to the common mode voltage minus the gate-to-source voltage of the transistors 460, 720, 915, 954, 960, 990. In such example operations, the transistors 460, 720, 915, 954, 960, 990 isolate the minus input signal from voltage variations at the plus and minus common mode input signals responsive to the control circuitry 710, 930, 970 using the common mode voltage to operate in saturation mode. Advantageously, the transistors 460, 720, 915, 954, 960, 990 reduce voltage variations at the minus input signal during switching events of the switches 410, 420, 942, 946, 974, 976. Control proceeds to perform the operations of Blocks 640, 645, 650, 655, 660, 665, 670 of FIG. 6, above.

Example methods are described with reference to the flowchart illustrated in FIG. 10. However, many other methods of implementing the mismatch correction circuitry 160, 265, 700, 830, 835, 905, 910, or more generally, the common mode regulator circuitry 150, 230, 800 of FIGS. 1, 2, and 8 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and things, the phrase “at least one of A and B” refers to implementations including any of (1) at least one A, (2) at least one B, or (3) at least one A and at least one B. Similarly, as used herein in the context of describing structures, components, items, objects and things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is at least one of not feasible or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by at least one of the connection reference or relative movement between those elements unless otherwise indicated. As such, connection references do not necessarily infer that two elements are directly connected or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, or ordering in any way, but are merely used as at least one of labels or arbitrary names to distinguish elements for ease of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to at least one of manufacturing tolerances or other real-world imperfections. For example, “approximately” and “about” may indicate such dimensions may be within a tolerance range of +/−10% unless otherwise specified herein.

As used herein, the phrase “in communication,” including variations thereof, encompasses one of or a combination of direct communication or indirect communication through one or more intermediary components, and does not require direct physical (e.g., wired) communication or constant communication, but rather also includes selective communication at least one of periodic intervals, scheduled intervals, aperiodic intervals, or one-time events.

As used herein, “programmable circuitry” is defined to include at least one of (i) one or more special purpose electrical circuits (e.g., an application specific circuit (ASIC)) structured to perform specific operation(s) and including one or more semiconductor-based logic devices (e.g., electrical hardware implemented by one or more transistors), or (ii) one or more general purpose semiconductor-based electrical circuits programmable with instructions to perform one or more specific functions(s) or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., at least one of programmed or hardwired) at a time of manufacturing by a manufacturer to at least one of perform the function or be configurable (or re-configurable) by a user after manufacturing to perform the function/or other additional or alternative functions. The configuring may be through at least one of firmware or software programming of the device, through at least one of a construction or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage and/or current sources) may instead include only the semiconductor elements within a single physical device (e.g., at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include at least one of a chassis ground, an Earth ground, a floating ground, a virtual ground, a digital ground, a common ground, or any other form of ground connection applicable to, or suitable for, the teachings of this description. Unless otherwise stated, “about,” “approximately,” or “substantially” preceding a value means +/−10 percent of the stated value, or, if the value is zero, a reasonable range of values around zero.

Modifications are possible in the described embodiments, and other embodiments are possible, within the scope of the claims.

What is claimed is:

1. An apparatus comprising:
amplifier circuitry having a first input, a second input, and an output;
a resistor having a first terminal and a second terminal, the first terminal of the resistor coupled to the output of the amplifier circuitry;
a first switch having a first terminal and a second terminal;
a second switch having a first terminal and a second terminal;
a third switch having a first terminal and a second terminal, the first terminal of the third switch coupled to the first terminal of the second switch;
a fourth switch having a first terminal and a second terminal, the first terminal of the fourth switch coupled to the first terminal of the first switch;
a first transistor having a first terminal and a second terminal, the first terminal of the first transistor coupled to the first input of the amplifier circuitry and the second terminal of the resistor, the second terminal of the first transistor coupled to the second terminal of the first switch and the second terminal of the fourth switch; and
a second transistor having a first terminal and a second terminal, the first terminal of the second transistor coupled to the second input of the amplifier circuitry, the second terminal of the second transistor coupled to the second terminal of the second switch and the second terminal of the third switch.

2. The apparatus of claim 1, wherein the amplifier circuitry is first amplifier circuitry, the resistor is a first resistor, and the apparatus is further comprising:
second amplifier circuitry having an output; and
a second resistor having a first terminal and a second terminal, the first terminal of the second resistor is coupled to the output of the second amplifier circuitry, the second terminal of the second resistor is coupled to the second input of the first amplifier circuitry and the first terminal of the second transistor.

3. The apparatus of claim 1, wherein the amplifier circuitry is first amplifier circuitry, the resistor is a first resistor, the first transistor further has a control terminal, the second transistor further has a control terminal, and the apparatus further comprising:
a second resistor having a first terminal and a second terminal, the first terminal of the second resistor is coupled to the first input of the first amplifier circuitry and the first terminal of the first transistor;
a third resistor having a first terminal and a second terminal, the first terminal of the third resistor is coupled to the second input of the first amplifier circuitry and the first terminal of the second transistor; and
second amplifier circuitry having a first input, a second input, and an output, the first input of the second amplifier circuitry is coupled to the second terminal of the second resistor and the second terminal of the third resistor, the second input of the second amplifier circuitry is coupled to the control terminal of the first transistor, the control terminal of the second transistor, and the output of the second amplifier circuitry.

4. The apparatus of claim 1, wherein the first transistor further has a control terminal, and the second transistor further has a control terminal, the control terminal of the first transistor is coupled to the first input of the amplifier circuitry, the second terminal of the resistor, and the first terminal of the first transistor, the control terminal of the second transistor is coupled to the second input of the amplifier circuitry and the first terminal of the second transistor.

5. The apparatus of claim 4, further comprising:
a third transistor having a first terminal, a second terminal, and a control terminal, the first terminal of the third transistor is coupled to the first input of the amplifier circuitry, the second terminal of the resistor, the first terminal of the first transistor, and the control terminal of the first transistor, the second terminal of the third transistor is coupled to the second terminal of the first switch, the second terminal of the fourth switch, and the second terminal of the first transistor, the control terminal of the third transistor is coupled to the second input of the amplifier circuitry; and
a fourth transistor having a first terminal, a second terminal, and a control terminal, the first terminal of the fourth transistor is coupled to the second input of the amplifier circuitry, the first terminal of the second transistor, and the control terminal of the second transistor, the second terminal of the fourth transistor is coupled to the second terminal of the second switch, the second terminal of the third switch, and the second terminal of the second transistor, the control terminal of the fourth transistor is coupled to the first input of the amplifier circuitry.

6. The apparatus of claim 1, further comprising current regulator circuitry having a first input, a second input, and a control terminal, the first input of the current regulator circuitry is coupled to the first terminal of the first switch and the first terminal of the fourth switch, the second input of the current regulator circuitry is coupled to the first terminal of the second switch and the first terminal of the third switch, the control terminal of the current regulator circuitry is coupled to the output of the amplifier circuitry.

7. The apparatus of claim 6, wherein the first switch, the second switch, the third switch, the fourth switch, the first transistor, and the second transistor are first mismatch correction circuitry, the current regulator circuitry is current sink circuitry, and the apparatus further comprising:
second mismatch correction circuitry having a first terminal, a second terminal, a third terminal, and a fourth terminal; and
current source circuitry having a first output, a second output, and a control terminal, the first output of the current source circuitry is coupled to the first input of the amplifier circuitry, the second terminal of the resistor, the first terminal of the first transistor, and the first terminal of the second mismatch correction circuitry, the second output of the current source circuitry is coupled to the second input of the amplifier circuitry, the first terminal of the second transistor, and the second terminal of the second mismatch correction circuitry.

8. An apparatus comprising:
amplifier circuitry having a first input and a second input;
a first switch having a terminal and a second terminal;
a second switch having a first terminal and a second terminal, the first terminal of the second switch coupled to the first terminal the first switch;
a third switch having a first terminal and a second terminal;
a fourth switch having a first terminal and a second terminal, the first terminal of the fourth switch coupled to the first terminal of the third switch;
a first transistor having a first terminal, a second terminal, and a control terminal, the first terminal of the first transistor coupled to the second terminal of the first switch and the first terminal of the third switch;
a second transistor having a first terminal, a second terminal, and a control terminal, the first terminal of the second transistor coupled to second terminal of the second switch and the second terminal of the fourth switch; and
control circuitry having a first terminal, a second terminal, and a third terminal, the first terminal of the control circuitry coupled to the first input of the amplifier circuitry and the second terminal of the first transistor, the second terminal of the control circuitry coupled to the second input of the amplifier circuitry and the second terminal of the second transistor, the third terminal of the control circuitry coupled to the control terminal of the first transistor and the control terminal of the second transistor.

9. The apparatus of claim 8, wherein the control circuitry includes:
buffer circuitry having an input and an output, the output of the buffer circuitry is coupled to the control terminal of the first transistor and the control terminal of the second transistor;
a first resistor having a first terminal and a second terminal, the first terminal of the first resistor is coupled to the first input of the amplifier circuitry and the second terminal of the first transistor; and
a second resistor having a first terminal and a second terminal, the first terminal of the second resistor is coupled to the second input of the amplifier circuitry and the second terminal of the second transistor, the second terminal of the second resistor is coupled to the input of the buffer circuitry and the second terminal of the first resistor.

10. The apparatus of claim 8, wherein the amplifier circuitry is first amplifier circuitry, and the apparatus further comprising second amplifier circuitry having a first input, a second input, a first output and a second output, the first input of the second amplifier circuitry is coupled to the first input of the first amplifier circuitry and the second terminal of the first transistor, the second input of the second amplifier circuitry is coupled to the second input of the first amplifier circuitry and the second terminal of the second transistor, the first output of the second amplifier circuitry is coupled to the first terminal of the first switch and the first terminal of the second switch, the second output of the second amplifier circuitry is coupled to the first terminal of the third switch and the first terminal of the fourth switch.

11. The apparatus of claim 8, wherein the amplifier circuitry further has a first output and a second output, and the apparatus further comprising:
a first resistor having a first terminal and a second terminal, the first terminal of the first resistor is coupled to the first output of the amplifier circuitry;
a second resistor having a first terminal and a second terminal, the first terminal of the second resistor is coupled to the second output of the amplifier circuitry;
a third transistor having a first terminal and a control terminal; and
a fourth transistor having a first terminal and a control terminal, the first terminal of the fourth transistor is coupled to the first terminal of the first switch and the first terminal of the second switch, the control terminal of the fourth transistor is coupled to the second terminal of the first resistor, the second terminal of the second resistor, the first terminal of the third transistor, and the control terminal of the third transistor.

12. The apparatus of claim 8, wherein the control terminal of the first transistor is coupled to the first input of the amplifier circuitry and the second terminal of the first transistor, and the control terminal of the second transistor is coupled to the second input of the amplifier circuitry and the second terminal of the second transistor.

13. The apparatus of claim 8, wherein the control circuitry includes:
a third transistor having a first terminal, a second terminal, and a control terminal, the first terminal of the third transistor is coupled to the first input of the amplifier circuitry, the second terminal of the first transistor, and the control terminal of the first transistor, the second terminal of the third transistor is coupled to the second terminal of the first switch, the second terminal of the third switch, and the second terminal of the first transistor, the control terminal of the third transistor is coupled to the second input of the amplifier circuitry; and
a fourth transistor having a first terminal, a second terminal, and a control terminal, the first terminal of the fourth transistor is coupled to the second input of the amplifier circuitry, the second terminal of the second transistor, and the control terminal of the second transistor, the second terminal of the fourth transistor is coupled to the second terminal of the second switch, the second terminal of the fourth switch, and the second terminal of the second transistor, the control terminal of the fourth transistor is coupled to the first input of the amplifier circuitry.

14. The apparatus of claim 8, wherein the amplifier circuitry further has an output, and the apparatus is further comprising current sink circuitry having a first input, a second input, and a control terminal, the first input of the current sink circuitry is coupled to the first terminal of the first switch and the first terminal of the second switch, the second input of the current sink circuitry is coupled to the first terminal of the third switch and the first terminal of the fourth switch, the control terminal of the current sink circuitry is coupled to the output of the amplifier circuitry.

15. The apparatus of claim 14, wherein the first switch, the second switch, the third switch, the fourth switch, the first transistor, and the second transistor are first mismatch correction circuitry, and the apparatus further comprising:
second mismatch correction circuitry having a first terminal, a second terminal, a third terminal, and a fourth terminal; and
current source circuitry having a first output, a second output, and a control terminal, the first output of the current source circuitry is coupled to the first input of the amplifier circuitry, the second terminal of the first transistor, and the first terminal of the second mismatch correction circuitry, the second output of the current source circuitry is coupled to the second input of the amplifier circuitry, the second terminal of the second transistor, and the second terminal of the second mismatch correction circuitry.

16. An apparatus comprising:
amplifier circuitry having a first input, a second input, and an output;
common mode regulator circuitry having a terminal coupled to the output of the amplifier circuitry, the common mode regulator circuitry configured to:
generate a first current and a second current responsive to a difference between a first input voltage at the first input of the amplifier circuitry and an output voltage at the output of the amplifier circuitry;
regulate a common mode voltage of the first input voltage and a second input voltage at the second input of the amplifier circuitry responsive to generating the first current and the second current;
compensate the first input voltage and the second input voltage for mismatch between the first current and the second current; and
compensate the first current and the second current for a difference between the first input voltage and the second input voltage.

17. The apparatus of claim 16, wherein the common mode regulator circuitry is further configured to:
sink the first current from the first input voltage for a first portion of a clock cycle;
sink the second current from the second input voltage for the first portion of the clock cycle;
sink the first current from the second input voltage for a second portion of the clock cycle; and
sink the second current from the first input voltage for the second portion of the clock cycle.

18. The apparatus of claim 16, wherein the common mode regulator circuitry is further configured to:
determine the common mode voltage between the first input voltage and the second input voltage; and
control the compensation of the first current and the second current for the difference between the first input voltage and the second input voltage based on the common mode voltage.

19. The apparatus of claim 16, wherein the common mode regulator circuitry is current sink circuitry, and the apparatus further comprising:
current source circuitry coupled to the amplifier circuitry, the current source circuitry configured to generate a third current and a fourth current responsive to the difference between the output voltage and the first input voltage; and
mismatch circuitry coupled to the amplifier circuitry and the current source circuitry, the mismatch circuitry configured to:
compensate the first input voltage and the second input voltage for mismatch between the third current and the fourth current; and
compensate the third current and the fourth current for the difference between the first input voltage and the second input voltage.

20. The apparatus of claim 19, further comprising:
the current sink circuitry is further configured to source the first current and the second current from the first input voltage and the second input voltage responsive to the output voltage being greater than the first input voltage; and
the current source circuitry is further configured to supply the third current and the fourth current to the first input voltage and the second input voltage responsive to the output voltage being less than the first input voltage.
